(19) United States
(12) Patent Application Publication
(10) Pub. No.: US 2024/0400374 A1
(43) Pub. Date: Dec. 5, 2024

(54) MEMS DEVICE AND METHOD FOR MANUFACTURING MEMS DEVICE

(71) Applicant: ROHM CO., LTD., Kyoto (JP)

(72) Inventors: Toma FUJITA, Kyoto-shi (JP); Martin Wilfried HELLER, Kyoto-shi (JP); Naoki IZUMI, Kyoto-shi (JP)

(73) Assignee: ROHM CO., LTD., Kyoto (JP)

(21) Appl. No.: 18/676,461

(22) Filed: May 28, 2024

(30) Foreign Application Priority Data
Jun. 2, 2023 (JP) 2023-091473

(51) Int. Cl. B81B 3/00; B81C 1/00; G01P 15/08; G01P 15/125

(52) U.S. Cl. CPC B81B 3/0008; B81C 1/00968; G01P 15/0802; G01P 15/125; B81B 2201/0235; B81B 2203/0118; B81B 2203/0307; B81B 2203/04; B81B 2207/07; B81B 2207/092; B81C 2201/0132; B81C 2203/0118; G01P 2015/0871

(57) ABSTRACT

The MEMS device includes a device wafer having a first principal surface and a second principal surface that is on the opposite side of to the first principal surface, a cap wafer facing the first principal surface of the device wafer, and a bonding layer bonding the device wafer and the cap wafer. The device wafer includes a device substrate having a cavity recessed in the Z direction from the first principal surface toward the second principal surface, a sensor unit that is positioned in the cavity and includes a fixed electrode and a movable electrode facing the fixed electrode, and a bump stopper that is disposed on a surface of the movable electrode, the surface being a surface on the side of the first principal surface, and that restricts displacement of the movable electrode in a direction moving closer to the cap wafer in the Z direction.

### TECHNICAL FIELD

The present disclosure relates to a MEMS device and a method for manufacturing the MEMS device.

### BACKGROUND ART

Micro-electromechanical system (MEMS) sensors manufactured using a semiconductor microfabrication technique are known. As one example of the MEMS sensor, JP 2015-217473 A discloses an acceleration sensor. The acceleration sensor according to JP 2015-217473 A includes a sensor unit having a fixed electrode and a movable electrode, and is configured to detect acceleration by detecting a change in the capacitance of the sensor unit. This sensor unit detects an acceleration by detecting change in the capacitance according to a displacement of the movable electrode, the displacement corresponding to the acceleration exerted thereto.

### BRIEF DESCRIPTION OF DRAWINGS

FIG. 1 is a plan view of a MEMS device according to an embodiment of the present disclosure;

FIG. 2 is a cross-sectional view of a movable electrode of the MEMS device, taken along line II-II in FIG. 1;

FIG. 3 is a cross-sectional view of a fixed electrode of the MEMS device, taken along line III-III in FIG. 1;

FIG. 4 is a bottom view of a device wafer, as viewed from a Z2-side;

FIG. 5 is a plan view of a cap wafer, as viewed from a Z1-side;

FIG. 6 is a cross-sectional view taken along line VI-VI in FIG. 1;

FIG. 7 is a diagram illustrating one step of forming a cap wafer;

FIG. 8 is a diagram illustrating a step subsequent to the step in FIG. 7;

FIG. 9 is a diagram illustrating a step subsequent to the step in FIG. 8;

FIG. 10 is a diagram illustrating a step subsequent to the step in FIG. 9;

FIG. 11 is a diagram illustrating a step subsequent to the step in FIG. 10;

FIG. 12 is a diagram illustrating a step subsequent to the step in FIG. 11;

FIG. 13 is a diagram illustrating one step of forming a device wafer;

FIG. 14 is a diagram illustrating a step subsequent to the step in FIG. 13;

FIG. 15A is a diagram illustrating a step subsequent to the step in FIG. 14;

FIG. 15B is a plan view of the sensor unit illustrated in FIG. 15A, as viewed from the Z2-side;

FIG. 15C is a cross-sectional view taken along line XVC-XVC in FIG. 15B;

FIG. 16A is a diagram illustrating a step subsequent to the step in FIG. 15A;

FIG. 16B is a plan view of the sensor unit illustrated in FIG. 16A, as viewed from the Z2-side;

FIG. 16C is a cross-sectional view taken along line XVIC-XVIC in FIG. 16B;

FIG. 17A is a diagram illustrating a step subsequent to the step in FIG. 16A;

FIG. 17B is a plan view of the sensor unit illustrated in FIG. 17A, as viewed from the Z2-side;

FIG. 17C is a cross-sectional view taken along line XVIIC-XVIIC in FIG. 17B;

FIG. 18A is a diagram illustrating a step subsequent to the step in FIG. 17A;

FIG. 18B is a plan view of the sensor unit illustrated in FIG. 18A, as viewed from the Z2-side;

FIG. 18C is a cross-sectional view taken along line XVIIIC-XVIIIC in FIG. 18B;

FIG. 19A is a diagram illustrating a step subsequent to the step in FIG. 18A;

FIG. 19B is a plan view of the sensor unit illustrated in FIG. 19A, as viewed from the Z2-side;

FIG. 19C is a cross-sectional view taken along line XIXC-XIXC in FIG. 19B;

FIG. 20A is a diagram illustrating a step subsequent to the step in FIG. 19A;

FIG. 20B is a plan view of the sensor unit illustrated in FIG. 20A, as viewed from the Z2-side;

FIG. 20C is a cross-sectional view taken along line XXC-XXC in FIG. 20B;

FIG. 21 is a view illustrating one step of bonding the cap wafer and the device wafer;

FIG. 22 is a diagram illustrating a step subsequent to the step in FIG. 21;

FIG. 23 is a diagram illustrating a step subsequent to the step in FIG. 22;

FIG. 24 is a diagram illustrating a step subsequent to the step in FIG. 23;

FIG. 25A is a diagram illustrating a step subsequent to the step illustrated in FIG. 14, according to a modification;

FIG. 25B is a plan view of the sensor unit illustrated in FIG. 25A, as viewed from the Z2-side;

FIG. 25C is a cross-sectional view taken along line XXVC-XXVC in FIG. 25B;

FIG. 26A is a diagram illustrating a step subsequent to the step in FIG. 25A;

FIG. 26B is a plan view of the sensor unit illustrated in FIG. 26A, as viewed from the Z2-side;

FIG. 26C is a cross-sectional view taken along line XXVIC-XXVIC in FIG. 26B;

FIG. 27A is a diagram illustrating a step subsequent to the step in FIG. 26A;

FIG. 27B is a plan view of the sensor unit illustrated in FIG. 27A, as viewed from the Z2-side;

FIG. 27C is a cross-sectional view taken along line XXVIIC-XXVIIC in FIG. 27B;

FIG. 28A is a diagram illustrating a step subsequent to the step in FIG. 27A;

FIG. 28B is a plan view of the sensor unit illustrated in FIG. 28A, as viewed from the Z2-side;

FIG. 28C is a cross-sectional view taken along line XXVIIIC-XXVIIIC in FIG. 28B;

FIG. 29A is a diagram illustrating a step subsequent to the step in FIG. 28A;

FIG. 29B is a plan view of the sensor unit illustrated in FIG. 29A, as viewed from the Z2-side;

FIG. 29C is a cross-sectional view taken along line XXIXC-XXIXC in FIG. 29B;

FIG. 30A is a diagram illustrating a step subsequent to the step in FIG. 29A;

FIG. 30B is a plan view of the sensor unit illustrated in FIG. 30A, as viewed from the Z2-side;

FIG. 30C is a cross-sectional view taken along line XXXC-XXXC in FIG. 30B; and

FIG. 31 is a diagram similar to FIG. 2 but of a MEMS device according to a modification.

### DETAILED DESCRIPTION

A MEMS device according to an embodiment of the present disclosure will now be explained with reference to the accompanying drawings. The following description is merely exemplary in nature, and is not intended to limit the present disclosure, nor objects the present disclosure is applied and use thereof. Furthermore, the drawings are schematic representations, and ratios of the dimensions and the like are different from those in the reality.

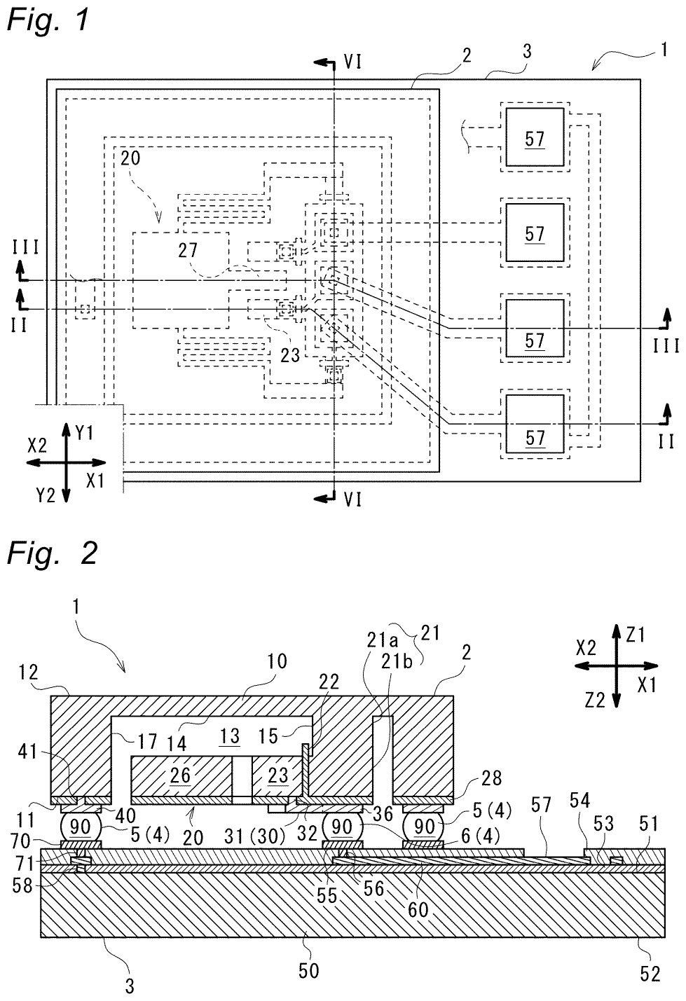

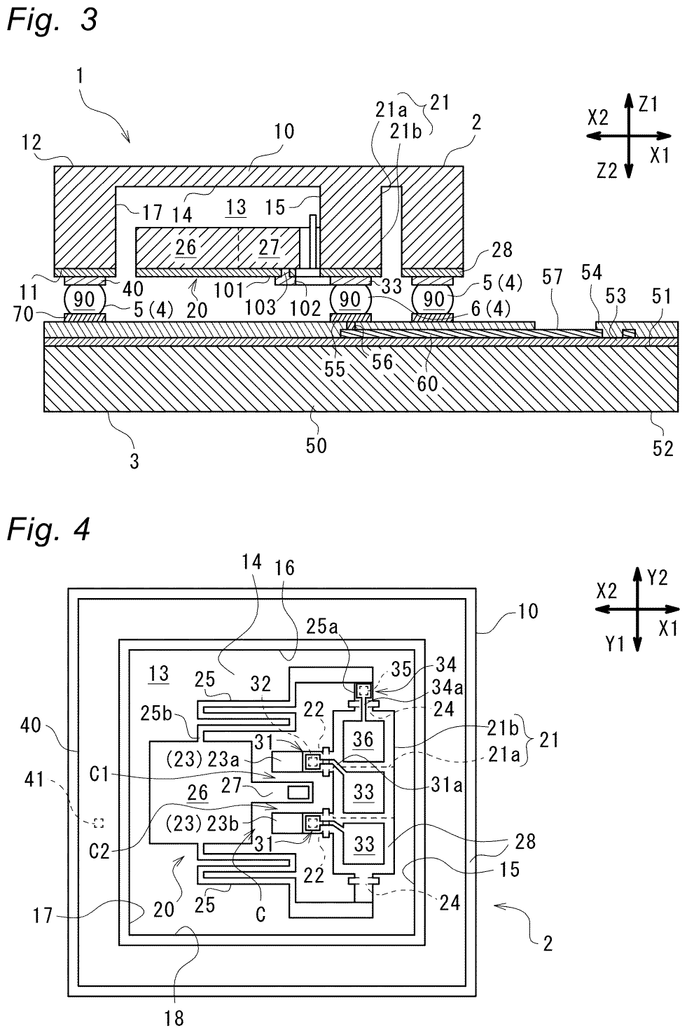

FIG. 1 is a plan view of a MEMS device 1 according to an embodiment of the present disclosure. The MEMS device 1 is a MEMS sensor that is manufactured using a semiconductor microfabrication technique. FIG. 2 is a cross-sectional view of a movable electrode 27 of the MEMS device 1 taken along line II-II in FIG. 1. FIG. 3 is a cross-sectional view of a fixed electrode 23 of the MEMS device 1 taken along line III-III in FIG. 1.

In the following description, for the convenience, among the directions extending along the respective sides of the MEMS device 1 in the plan view illustrated in FIG. 1, the left-right direction will be referred to as an X direction, and the up-down direction will be referred to as a Y direction. The thickness direction (up-down direction) of the MEMS device 1 in the cross-sectional views illustrated in FIGS. 2 and 3 will be referred to as a Z direction. In particular, the right side in FIG. 1 will be referred to as an X1-side, the left side will be referred to as an X2-side, the upper side will be referred to as a Y1-side, and the lower side will be referred to as a Y2-side. In FIGS. 2 and 3, the upper side will be referred to as a Z1-side, and the lower side will be referred to as a Z2-side.

### (Overall Configuration of MEMS Device)

As illustrated in FIGS. 1 to 3, the MEMS device 1 includes a device wafer 2 that is on the Z1-side and has a sensor unit 20, a cap wafer 3 that is on the Z2-side of the device wafer 2, and a bonding layer 4 that bonds the device wafer 2 and the cap wafer 3.

### (Device Wafer)

FIG. 4 is a bottom view of the device wafer 2, as viewed from the Z2-side. As illustrated in FIGS. 2 to 4, the device wafer 2 has a first principal surface 11 that is on the Z2-side and that extends in parallel with the X direction and the Y direction; and a second principal surface 12 that is on the opposite side of the first principal surface 11, that is, on the Z1-side and that extends in parallel with the X direction and the Y direction. The device wafer 2 then includes a device substrate 10 having a cavity 13 recessed from the first principal surface 11 toward the Z1-side, a sensor unit 20 positioned inside the cavity 13, and a device wiring 30 to be electrically connected to the sensor unit 20.

The device substrate 10 is made of silicon doped with p-type impurities or n-type impurities at a high concentration, and has conductivity.

The peripheral walls defining the cavity 13 includes: a rectangular bottom wall 14; a first vertical wall 15 extending from the X1-side edge of the bottom wall 14 toward the Z2-side; a second vertical wall 16 extending from the Y2-side edge of the bottom wall 14 toward the Z2-side; a third vertical wall 17 extending from the X2-side edge of the bottom wall 14 toward the Z2-side; and a fourth vertical wall 18 extending from the Y1-side edge of the bottom wall 14 toward the Z2-side.

The sensor unit 20 includes an anchor 21 fixed to the bottom wall 14, a fixed electrode 23 connected to the anchor 21, a spring 25 connected to the anchor 21, a mass 26 supported by the spring 25, and a movable electrode 27 connected to the mass 26.

FIG. 6 is a cross-sectional view of the anchor 21 on a Y-Z plane, taken along line VI-VI in FIG. 1. Also referring to FIG. 6, the anchor 21 extends from the bottom wall 14 toward the Z2-side, and is spaced apart from all of the vertical walls 15 to 18. The anchor 21 includes a base end 21a that is on the Z1-side and fixed to the bottom wall 14, and a main body 21b that is on the Z2-side of the base end 21a. In the present embodiment, the size of the base end 21a is smaller in the Y direction than the main body 21b. In other words, because the anchor 21 is connected fixed to the bottom wall 14 via the base end 21a, which is smaller than the main body 21b, the package stress transmitted to the anchor 21 is reduced.

In the present embodiment, the fixed electrode 23 is provided as a pair, in a manner arranged side by side in the Y direction, on the X2-side of the anchor 21. The pair of fixed electrodes 23 include a first fixed electrode 23a and a second fixed electrode 23b respectively extending in the X direction. The pair of fixed electrodes 23 are mechanically connected to and electrically isolated from the anchor 21, via respective first isolation joints (hereinafter referred to as IJs) 22.

In the present embodiment, the spring 25 is provided as a pair, with their base ends 25a connected to the Y1-side and the Y2-side of the anchor 21, respectively, and extend in the Y direction, with a plurality of bends in the X direction, for example, in a manner enabled to stretch and to contract in the Y direction. The pair of springs 25 are mechanically connected to and electrically isolated from the anchor 21, via respective second IJs 24.

The mass 26 is supported between the tip ends 25b of the pair of springs 25, and is movable in the Y direction against the elastic force of the springs 25 when an inertial force is exerted thereto.

The movable electrode 27 is connected to the mass 26, and extends in the X direction, at a middle point between the pair of fixed electrodes 23 in the Y direction and at the same height position in the Z direction. In the following description, the springs 25, the mass 26, and the movable electrode 27, which are mechanically connected to and electrically isolated from the anchor 21 via the second IJs 24, will be sometimes collectively referred to as a movable electrode 27.

The anchor 21, the first IJs 22, the fixed electrodes 23, the springs 25, the mass 26, and the movable electrode 27 are all formed of the device substrate 10, and are conductive. In addition, all of the first IJs 22, the fixed electrodes 23, the springs 25, the mass 26, and the movable electrode 27 are released and separated from the bottom wall 14, on the Z2-side.

In the sensor unit 20, a capacitor C is configured by the pair of fixed electrodes 23 and the movable electrode 27 together. Specifically, the first fixed electrode 23a and the movable electrode 27 makes up a first capacitor C1, and the second fixed electrode 23b and the movable electrode 27 makes up a second capacitor C2.

The sensor unit 20 according to the present disclosure is configured as an acceleration sensor that detects acceleration in the Y direction by detecting changes in the capacitances of the first capacitor C1 and the second capacitor C2 via electrode pads 57 to be described later, respectively. The changes in the capacitances herein are changes that the capacitance of one of the first capacitor C1 and the second capacitor C2 increases and the capacitance of the other decreases, taking place when the sensor unit 20 is subjected to the acceleration in the Y direction and the movable electrode 27 becomes displaced in the Y direction. The sensor unit 20 may also be configured to detect an electric signal that is dependent on inertial force, e.g., accelerations in the X direction or the Z direction. In summary, the sensor unit 20 according to the present disclosure may be any sensor including a plurality of electrodes that are mechanically supported by a single anchor, as well as being electrically isolated from one another.

The first principal surface 11 of the device substrate 10 has a device insulating layer 28 laminated on the Z2-side. The device insulating layer 28 is made of silicon oxide. The device insulating layer 28 is also provided, among the elements of the sensor unit 20, on the anchor 21; on the fixed electrodes 23 at least in the areas near the first IJs 22, respectively; and on the area, among the area over the springs 25, the mass 26, near the second IJs 24, respectively.

In the present embodiment, the device insulating layer 28 extending from the anchor 21 toward the X2-side is terminated immediately on the fixed electrodes 23, at position just beyond the first IJs 22, respectively, to reserve areas for providing fixed electrode contacts 32, to be described later. Similarly, the device insulating layer 28 extending from the anchor 21 in the Y direction is terminated immediately on the movable electrode 27, that is, on the pair of springs 25 in this embodiment, at a position just beyond the second IJ 24, to reserve the area for providing a movable electrode contact 35, which will be described later.

The device wiring 30 includes fixed electrode wirings 31 connected to the fixed electrodes 23, respectively, and a movable electrode wiring 34 connected to the movable electrode 27. The device wiring 30 are laminated on the Z2-side of the device insulating layer 28.

The device wiring 30 is made of a material having wettability with respect to the bonding layer 4, and causing no eutectic diffusion in the bonding layer 4. In the present embodiment, because the bonding layer 4 is made of an aluminum-germanium eutectic (hereinafter referred to as an AlGe eutectic) 90, as will be described later, conductive polysilicon is used as a material of the device wiring 30 that has wettability to the AlGe eutectic 90 and does not cause the diffusion of the eutectic reaction of the AlGe eutectic 90.

Other than the conductive polysilicon, the device wiring 30 may be made of a conductive material selected from the group consisting of a polycide alloy, a titanium nitride alloy, and a titanium tungsten alloy. These materials also have wettability to the AlGe eutectic 90, and does not causing the diffusion of the AlGe eutectic.

Each of the fixed electrode wirings 31 includes, in a view from the Z2-side, a fixed electrode contact 32 penetrating the device insulating layer 28 in the Z direction, and is electrically connected to the corresponding fixed electrode 23; a fixed electrode bonding portion 33 positioned on the anchor 21; and a wiring 32a extending from the corresponding fixed electrode contact 32, across the corresponding first IJ 22 toward the X1-side, and to the corresponding fixed electrode bonding portion 33. The fixed electrode bonding portions 33 form a part of the fixed electrode wiring 31, and also serve as bonding portions to the cap wafer 3.

The movable electrode wiring 34 includes, in a view from the Z2-side, the movable electrode contact 35 that penetrates the device insulating layer 28 in the Z direction and that is electrically connected to the movable electrode 27 (in this embodiment, the base end 25a of the spring 25 positioned on the Y2-side); a movable electrode bonding portion 36 that is positioned on the anchor 21; and a wiring 34a that extends from the movable electrode contact 35, across the second IJ 24 toward the Y1-side, and to the movable electrode bonding portion 36. The movable electrode bonding portion 36 forms a part of the movable electrode wiring 34, and also serves as a bonding portion to the cap wafer 3.

In the present embodiment, because the pair of fixed electrodes 23 and the one movable electrode 27 are provided, the two fixed electrode wirings 31 and the one movable electrode wiring 34 are provided, accordingly. Therefore, the two fixed electrode bonding portions 33 and the one movable electrode bonding portion 36 are positioned accordingly on the Z2-side of the anchor 21.

Also laminated on the Z2-side of the device insulating layer 28 is a device outer peripheral bonding layer 40 extending along the outer periphery of the cavity 13, as viewed from the Z2-side. The device outer peripheral bonding layer 40 is laminated on the device insulating layer 28, that is, laminated in the same layer as the device wiring 30. The device outer peripheral bonding layer 40 is made of the same material as the device wiring 30, and has conductivity. The device outer peripheral bonding layer 40 further includes a device outer peripheral layer contact 41 that penetrates the device insulating layer 28 in the Z direction and electrically connects the device outer peripheral bonding layer 40 to the device substrate 10.

As illustrated in FIG. 4, the device wafer 2 further includes a bump stopper 100 that restricts excessive displacement of the movable electrode 27 toward the Z2-side. The bump stopper 100 is provided on the Z2-side surface of the movable electrode 27. In the present embodiment, the bump stopper 100 is positioned at the X1-side tip end of the Z2-side surface of the movable electrode 27 supported in a cantilever-like fashion by the mass 26.

In the present embodiment, the bump stopper 100 has a rectangular shape, in a view from the Z2-side. The bump stopper 100 has a width smaller than the width of the movable electrode 27 in the Y direction that is the short direction of the movable electrode 27 in a view of the movable electrode 27 from the Z2-side. To put it in other words, both edges 100a of the bump stopper 100 in the Y direction are positioned nearer to the center of the movable electrode 27 in the Y direction, than the both edges 27a of the movable electrode 27 in Y direction.

As illustrated in FIG. 3, the bump stopper 100 includes a stopper insulating layer 101 that is on the Z1-side, a stopper body 102 that is on the Z2-side, and a stopper contact 103 that penetrates the stopper insulating layer 101 in the Z direction and connects the stopper body 102 to the movable electrode 27.

The stopper insulating layer 101 is positioned in the same layer as the device insulating layer 28, is made of the same material as the device insulating layer 28 (that is, made of silicon oxide in the present embodiment), and is formed at the same time with the device insulating layer 28, in the same lamination process, which will be described later.

The stopper body 102 and the stopper contact 103 are made of a conductive inorganic material. In the present embodiment, the stopper body 102 and the stopper contact 103 are laminated in the same layer, and are positioned in the same layer and made of the same material as the device wiring 30 (that is, made of polysilicon in the present embodiment), and are formed at the same time with the device wiring 30, in the same lamination process, which will be described later.

A Z2-side surface 102a of the stopper body 102 has a surface roughness greater than the surface roughness of the first principal surface 11 of the device substrate 10. The surface roughness of the surface 102a of the stopper body 102 is, for example, 10 nm to 20 nm in Ra (arithmetic average roughness), in the present embodiment. It is possible to achieve a rough surface on the stopper main body 102 by, for example, forming a polysilicon layer on the stopper insulating layer 101 using chemical vapor deposition (CVD), and not followed any surface polishing.

To explain the action of the bump stopper 100, when the movable electrode 27 becomes displaced too far toward the Z2-side, that is, toward the cap wafer 3, the bump stopper 100 comes into contact with the cap wafer 3, thereby preventing the movable electrode 27 from coming into direct contact with the cap wafer 3. Furthermore, even when the cap wafer 3 becomes electrically charged, the bump stopper 100, which has conductivity, can release the electrical charge of the cap wafer 3 to the movable electrode 27 via the stopper contact 103. Therefore, the bump stopper 100 is prevented from becoming electrically charged. As a result, no electrostatic attraction is generated between the bump stopper 100 and the cap wafer 3.

Further, because the Z2-side surface of the bump stopper 100 has a greater surface roughness than that of the device substrate 10, the area by which the bump stopper 100 comes into contact with the cap wafer 3 is reduced. In other words, with the bump stopper 100, because no electrostatic attraction is generated between the cap stopper 100 and the cap wafer 3, and the cap stopper 100 and the cap wafer 3 is prevented from adhering to each other, it is possible to better suppress sticking of the bump stopper to the cap wafer 3.

### (Cap Wafer)

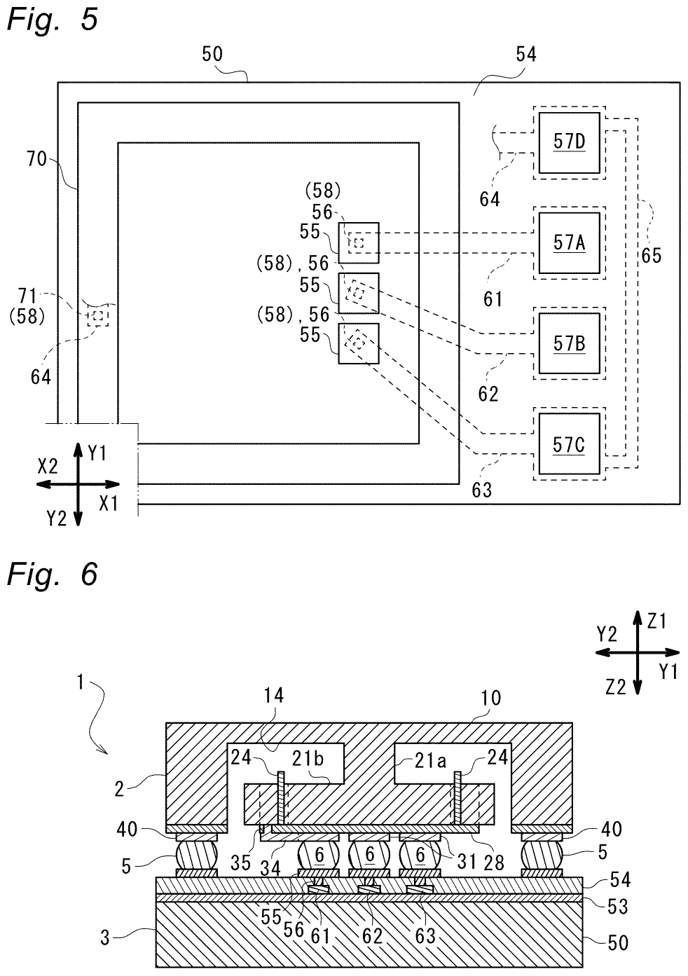

The cap wafer 3 will now be described, mainly with reference to FIGS. 2 and 5. FIG. 5 is a plan view of the cap wafer 3, as viewed from the Z1-side. To begin with, referring to FIG. 2, the cap wafer 3 includes a cap substrate 50, a first cap insulating layer 53 laminated on the Z1-side of the cap substrate 50, cap wirings 60 laminated on the Z1-side of the first cap insulating layer 53, a second cap insulating layer 54 laminated on the Z1-side of the first cap insulating layer 53, with the cap wiring 60 interposed between the second cap insulating layer 54 and the first cap insulating layer 53 in the Z direction, and bonding electrodes 55 laminated on the Z1-side of the second cap insulating layer 54.

The cap substrate 50 has a first principal surface 51 that is on the Z1-side and extends in parallel with the X direction and the Y direction, and a second principal surface 52 that is on the opposite side of the first principal surface 51 Z2-side and extends in parallel with the X direction and the Y direction. The cap substrate 50 is made of silicon doped with p-type impurities or n-type impurities at a high concentration, and has conductivity.

The cap substrate 50 has a size larger than that of the device substrate 10, in a plan view illustrated in FIG. 1. In the present embodiment, the cap substrate 50 is larger on the X1-side than the device substrate 10. On the part of the cap wafer 3 not covered by the device substrate 10, a plurality of electrode pads 57 via which electric signals are inputted from and outputted to a device (e.g., ASIC) outside the MEMS device 1 are provided.

The first cap insulating layer 53 is laminated on the entire surface of the cap substrate 50 on the Z1-side. The first cap insulating layer 53 is made of silicon oxide, and is an insulator.

As illustrated in FIG. 5, the cap wirings 60 include first to third cap wirings 61 to 63 that extend from one ends which are positioned correspondingly to the two fixed electrode bonding portions 33 and the one movable electrode bonding portion 36 of the device wafer 2, respectively, in the Z direction, to the outside of the cavity 13, and are connected to the first to third electrode pads 57A to 57C, respectively. The cap wiring 60 also includes a fourth cap wiring 64 connected from one end which is positioned correspondingly to the cap outer peripheral bonding layer 70 in the Z direction, which will be described later, to the fourth electrode pad 57D. The cap wiring 60 also includes a fifth cap wiring 65 that connects the third electrode pad 57C and the fourth electrode pad 57D.

The first to third cap wirings 61 to 63 are electrically connected to the respective bonding electrodes 55, via respective bonding electrode contacts 56 penetrating the second cap insulating layer 54 in the Z direction. The fourth cap wiring 64 is electrically connected to the cap substrate 50 via a cap wiring contact 58 penetrating the first cap insulating layer 53 in the Z direction, and conducts electricity to the cap outer peripheral bonding layer 70 via a cap outer peripheral layer contact 71 penetrating the second cap insulating layer 54 in the Z direction.

The cap wiring 60 and the electrode pads 57 are disposed on the first cap insulating layer 53, that is, the cap wiring 60 and the electrode pads 57 are laminated in the same layer and are made of the same material. In the present embodiment, each of the cap wiring 60 and the electrode pads 57 has a conductive three-layer structure including a titanium nitride (TiN) layer laminated on the first cap insulating layer 53, an aluminum copper alloy (AlCu) layer laminated on the Z1-side of the titanium nitride layer, and a TiN layer laminated on the AlCu layer on the Z1-side. The bonding electrode contacts 56 and the cap wiring contact 58 are made of tungsten surrounded by TiN, and are conductive.

The second cap insulating layer 54 is laminated on the Z1-side of the first cap insulating layer 53, and the cap wiring 60 is interposed between the second cap insulating layer 54 and the first cap insulating layer 53. The second cap insulating layer 54 is made of silicon oxide, and is an insulator. The second cap insulating layer 54 is not laminated at the portions corresponding to the plurality of respective electrode pads 57. As a result, the plurality of electrode pads 57 are exposed on the Z1-side of the cap wafer 3. In the present embodiment, the second cap insulating layer 54 is not removed in the area facing the sensor unit 20 from the Z2-side. The second cap insulating layer 54 can come contact with the bump stopper 100 when the movable electrode 27 becomes excessively displaced toward the Z2-side.

The bonding electrodes 55 are provided, on the Z1-side of the second cap insulating layer 54, at positions facing the fixed electrode bonding portions 33 and the movable electrode bonding portion 36 of the device wafer 2, respectively, from the Z2-side. That is, in the present embodiment, the bonding electrodes 55 are provided in total at three positions including positions facing the two fixed electrode bonding portion 33 and a position facing one movable electrode bonding portion 36, respectively. Each of the bonding electrodes 55 is electrically connected to the corresponding cap wiring 60 via the corresponding bonding electrode contact 56 penetrating the second cap insulating layer 54 in the Z direction.

The bonding electrodes 55 are made of TiN, and has conductivity. The bonding electrodes 55 act as a barrier layer that prevents diffusion of the eutectic reaction between aluminum and germanium in the bonding layer 4, which will be described later, toward the Z2-side, resultant of the eutectic reaction of aluminum and germanium.

A cap outer peripheral bonding layer 70 is also laminated on the Z1-side of the second cap insulating layer 54, at a position corresponding to the device outer peripheral bonding layer 40 in the Z direction. The cap outer peripheral bonding layer 70 is laminated on the second cap insulating layer 54, that is, laminated in the same layer as the bonding electrodes 55, is made of the same material as the bonding electrodes 55, and has conductivity.

### (Bonding Layer)

The bonding layer 4 will now be described, mainly with reference to FIGS. 1 and 2. As illustrated in FIGS. 1 and 2, the bonding layer 4 includes: an outer peripheral bonding layer 5 that extends along the device outer peripheral bonding layer 40 and the cap outer peripheral bonding layer 70, and that bonds the device outer peripheral bonding layer 40 and the cap outer peripheral bonding layer 70 in the Z direction; and an inner peripheral bonding layer 6 positioned between and bonds each of the three bonding electrodes 55 and corresponding one of the two fixed electrode bonding portions 33 and the one movable electrode bonding portion 36, in the Z direction.

The bonding layer 4 is an aluminum-germanium eutectic achieved by eutectic reaction between aluminum and germanium. With the outer peripheral bonding layer 5, the sensor unit 20 is sealed between the device wafer 2 and the cap wafer 3, inside of the space shielded from the outside. The inner peripheral bonding layer 6 can electrically connect the device wirings 30 of the device wafer 2 to the cap wiring 60 of the cap wafer 3. That is, the bonding layer 4 can electrically connect each of the device wirings 30 to the cap wirings 60, while bonding the device wafer 2 and the cap wafer 3 in the Z direction.

### (Method for Manufacturing MEMS Device)

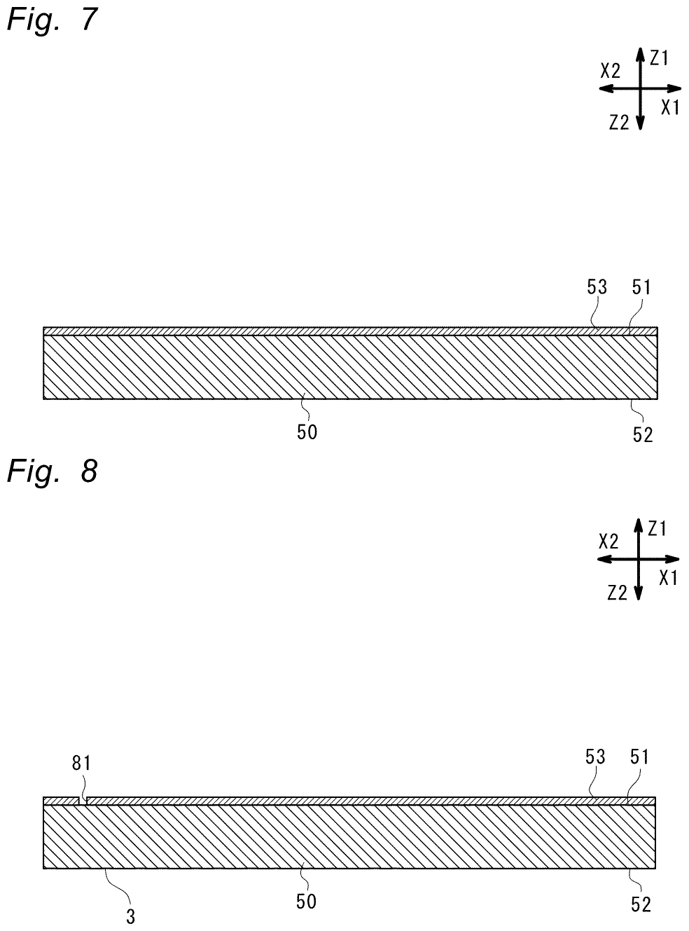

A method for manufacturing the MEMS device 1 will now be described with reference to FIGS. 7 to 24.

### (Step of Forming Cap Wafer)

To begin with, a step of forming the cap wafer 3 will be described with reference to FIGS. 7 to 12. As illustrated in FIG. 7, a cap substrate 50 that is a conductive silicon substrate doped with a p-type impurity or an n-type impurity at a high concentration is prepared. By thermally oxidizing the first principal surface 51 of the cap substrate 50, the first cap insulating layer 53 that is silicon oxide is formed on the first principal surface 51.

The first cap insulating layer 53 is then partially removed by etching using a known patterning technique, to form a via 81 having an opening at the portion corresponding to the cap wiring contact 58, as illustrated in FIG. 8.

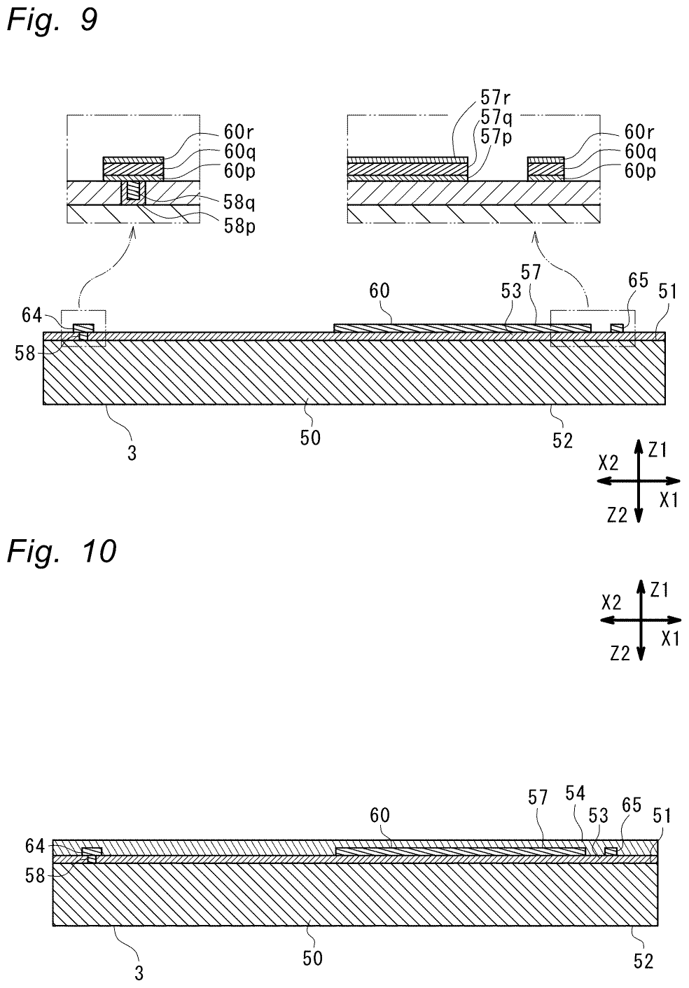

The cap wiring contact 58 is then formed in the via 81, as illustrated in FIG. 9. Specifically, referring to the enlarged view on the left side of FIG. 9, to begin with, a TiN layer 58p is formed in the recessed manner along the inner wall surface and the bottom wall surface of the via 81. Tungsten 58q is then laminated in the recess formed by the TiN layer 58p, and the surface is planarized by CMP, for example. The cap wiring contact 58 is formed thereby in the via 81.

The cap wirings 60 and the electrode pads 57 are then formed on the first cap insulating layer 53 using a known patterning technique. Specifically, TiN layers 60p, 57p are formed on the first cap insulating layer 53, and AlCu layers 60q, 57q are then formed on the TiN layers 60p, 57p, respectively. TiN layers 60r, 57r are then further formed on the AlCu layers 60q, 57q, respectively. In other words, each of the cap wirings 60 and the electrode pads 57 has a three-layer laminate structure including a TiN layer, an AlCu layer, and a TiN layer.

The second cap insulating layer 54 is then formed on the Z1-sides of the first cap insulating layer 53, the cap wiring 60, and the electrode pad 57, as illustrated in FIG. 10. The second cap insulating layer 54 is formed by, for example, chemical vapor deposition (CVD), using tetraethylsilane (TEOS) as a raw material. The second cap insulating layer 54 forms the passivation layer of the cap wiring 60. After the second cap insulating layer 54 is formed, the second cap insulating layer 54 is planarized using CMP, for example.

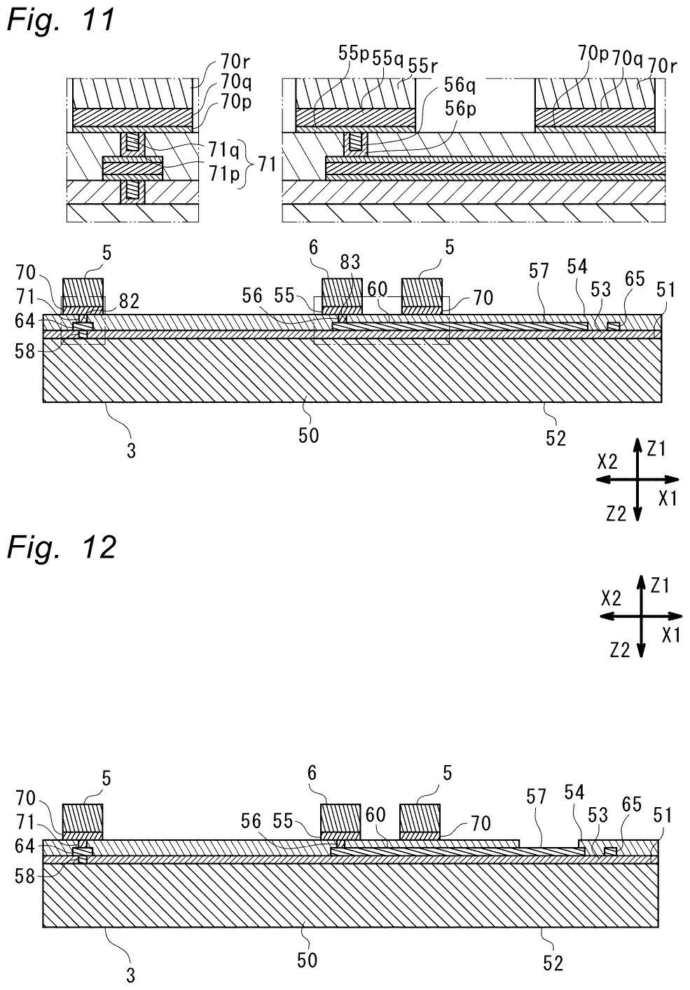

The second cap insulating layer 54 is then etched using a known patterning technique, as illustrated in FIG. 11, thereby forming vias 82, 83 with openings at the positions corresponding to the cap outer peripheral layer contact 71 and the bonding electrode contacts 56, respectively.

The cap outer peripheral layer contact 71 and the bonding electrode contacts 56 are then formed inside the vias 82, 83, respectively. Specifically, the cap outer peripheral layer contact 71 and the bonding electrode contacts 56 are formed in the same manner as the cap wiring contact 58 described above, and include recessed TiN layers 71p, 56p along the inner wall surfaces of the vias 82, 83, respectively, and tungsten 71q, 56q formed in the recesses of the respective TiN layers 71p, 56p.

Then, the bonding electrodes 55 and the cap outer peripheral bonding layer 70 are formed on the second cap insulating layer 54, using a known patterning technique. Specifically, TiN layers 55p, 70p are formed on the second cap insulating layer 54, to begin with, and then AlCu layers 55q, 70q are formed on the TiN layers 55p, 70p, respectively. Germanium layers 55r, 70r are then formed on the Z1-side of the AlCu layers 55q, 70q, respectively. The germanium layers 55r, 70r undergo a eutectic reaction with the AlCu layers 55q, 70q, to turn into an aluminum-germanium eutectic material that forms the bonding layer 4.

The second cap insulating layer 54 is then removed from the area covering the electrode pads 57 by etching, to expose the electrode pads 57, as illustrated in FIG. 12. At this time, the first cap insulating layer 53 and the second cap insulating layer 54 are left without being removed in the area where the sensor unit 20 faces in the Z direction. As a result, a finished cap wafer 3 is achieved.

### (Process of Forming Device Wafer)

A process of forming the device wafer 2 will now be described with reference to FIGS. 13 to 20. The device substrate 10 that is a conductive silicon substrate doped with a p-type impurity or an n-type impurity at a high concentration is prepared, as illustrated in FIG. 13.

The first principal surface 11 of the device substrate 10 is then thermally oxidized, although not illustrated, and patterning is applied to the thermal oxide film obtained by the thermal oxidation, to form a mask having openings at positions corresponding to the first IJs 22 and the second IJs 24. The device substrate 10 is then trenched toward the Z1-side, to form the trench 84, by anisotropic etching using the mask. After the trench 84 is formed, the mask is removed.

The device substrate 10 is then thermally oxidized from the Z2-side, as illustrated in FIG. 14, thereby forming the first IJs 22 and the second IJs 24 made of silicon oxide resultant of the thermal oxidization of the inner wall surface of the trench 84, and the device insulating layer 28 made of silicon oxide resultant of the thermal oxidization of the first principal surface 11 of the device substrate 10.

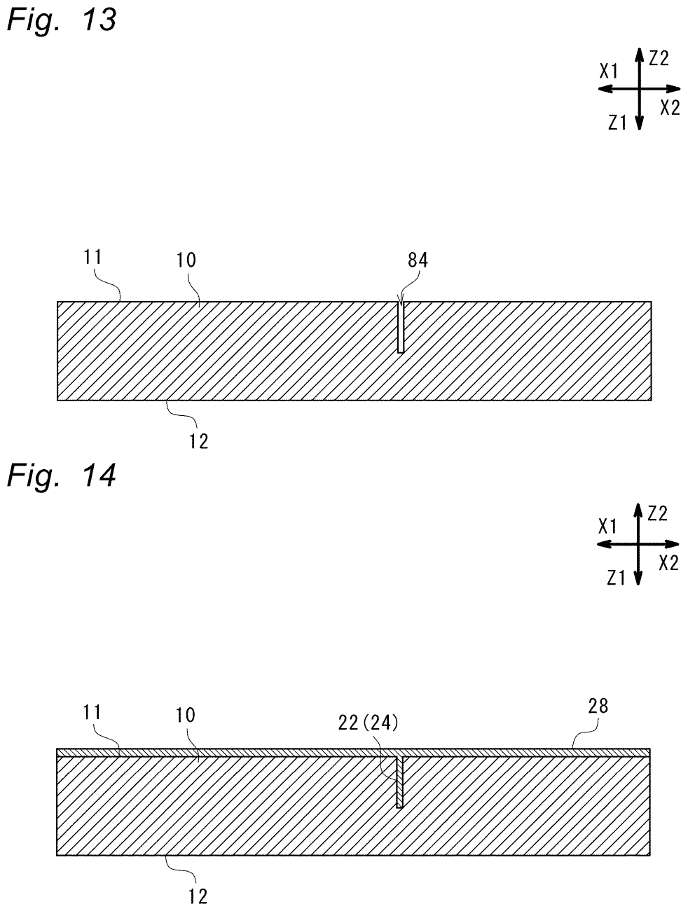

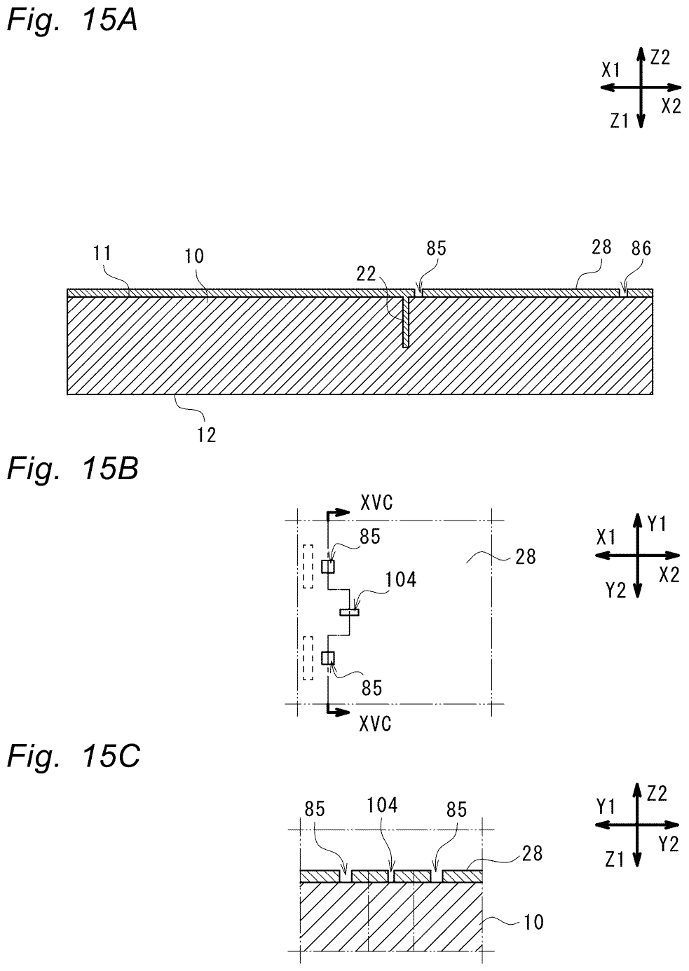

The device insulating layer 28 is then partially removed by etching using a known patterning technique, as illustrated in FIGS. 15A to 15C, thereby forming vias 85, 86, 104 having openings at the positions corresponding to the fixed electrode contacts 32, the device outer peripheral layer contact 41, and the stopper contact 103, respectively. Although not illustrated, a via is also formed on the device insulating layer 28 at a position corresponding to the movable electrode contact 35.

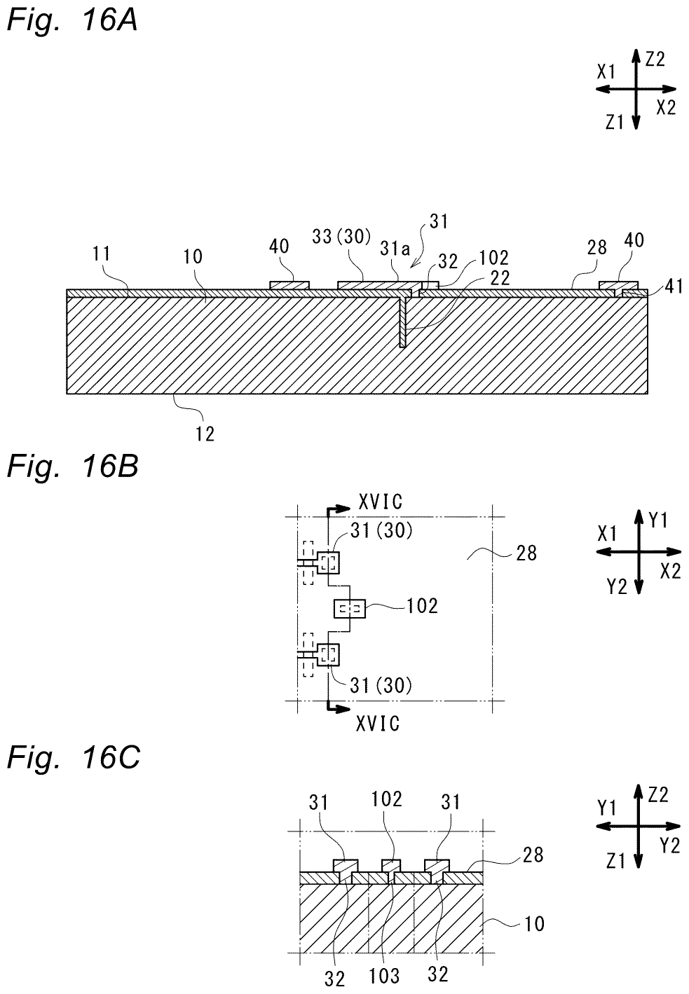

The device wirings 30, the device outer peripheral bonding layer 40, and the stopper body 102 are then laminated on the Z2-side of the device insulating layer 28, as illustrated in FIGS. 16A to 16C, using a known patterning technique. The fixed electrode contacts 32, the movable electrode contact 35, the device outer peripheral layer contact 41, and the stopper contact 103 are also formed in this process. The device wirings 30, the device outer peripheral bonding layer 40, the stopper body 102, and the contacts 32, 35, 41,103 are made of polysilicon doped with a p-type impurity or an n-type impurity at a high concentration, and are formed at the same time, that is, formed in the same layer by low-pressure CVD, for example.

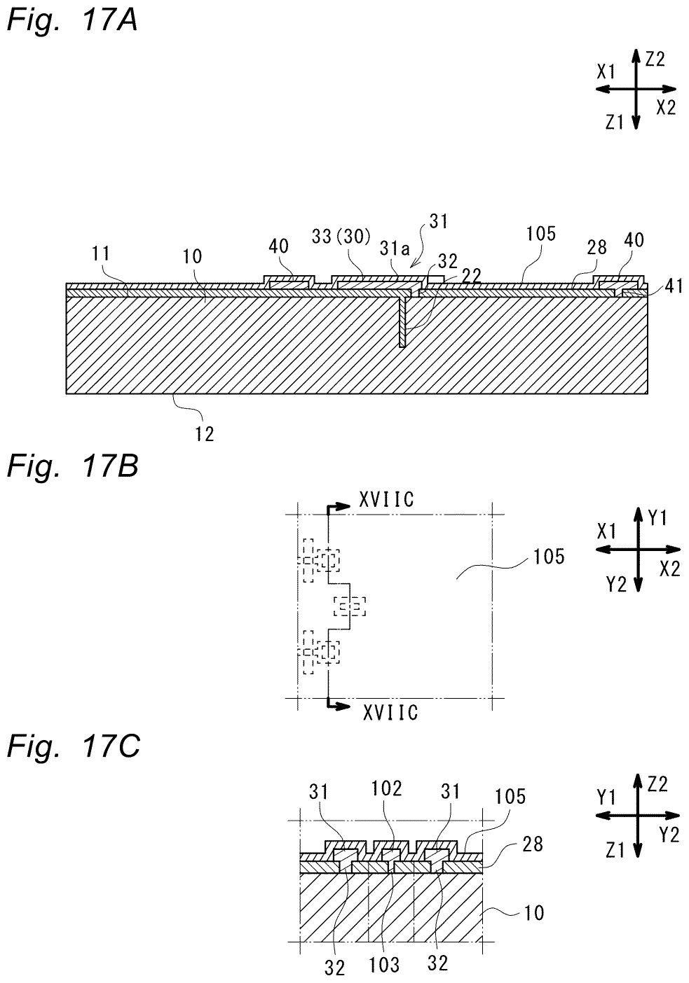

The passivation layer 105 is then is formed on the entire device substrate 10, from the Z2-side, as illustrated in FIGS. 17A to 17C. The passivation layer 105 is an oxide film made of silicon oxide.

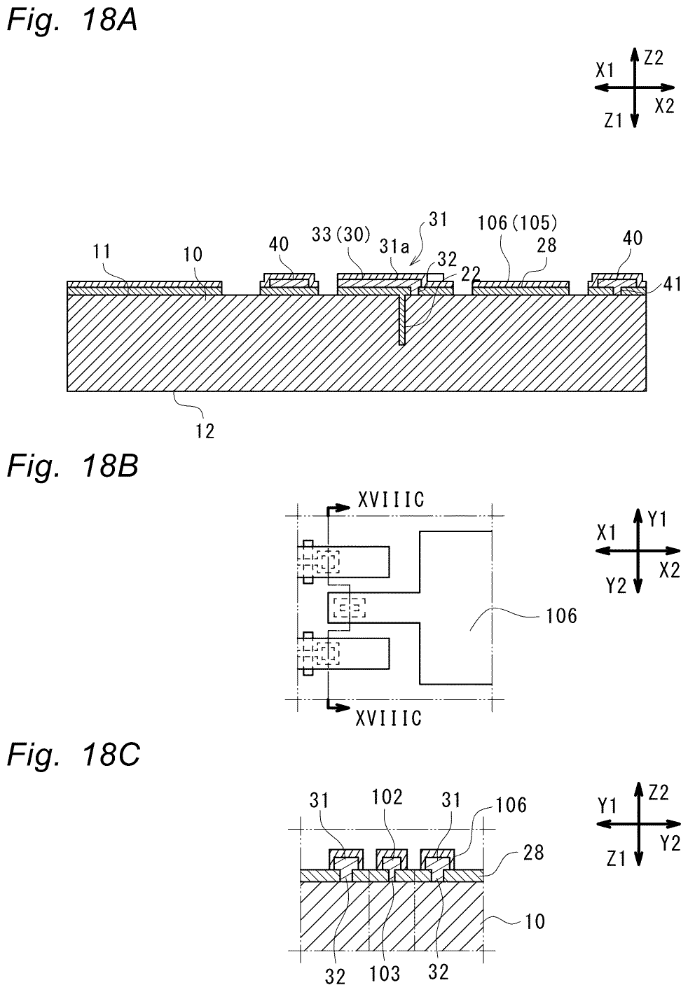

The passivation layer 105 and the device insulating layer 28 are then partially removed by etching, as illustrated in FIGS. 18A to 18C, to form a hard mask 106 that covers parts of the device substrate 10, and that has an opening in a portion where the cavity 13 is to be formed. The parts covered by the hard mask 106 are a part to be the sensor unit 20 and a part corresponding to the device outer peripheral bonding layer 40. The device substrate 10 therefore is exposed in the area not covered by the hard mask 106.

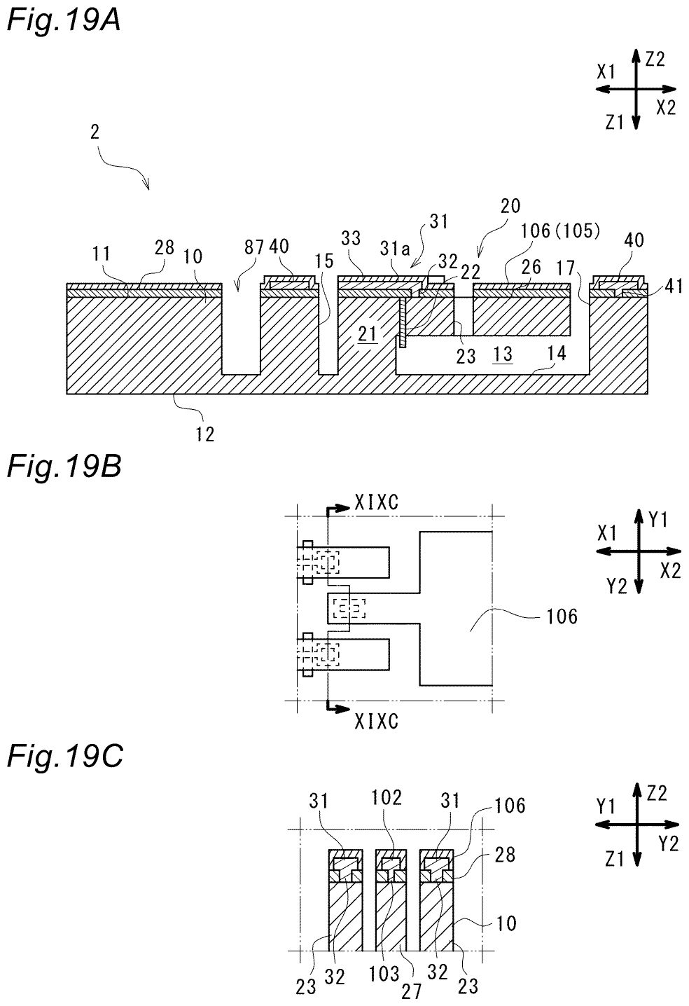

The device substrate 10 is then trenched toward the Z1-side by anisotropic etching using the hard mask 106, as illustrated in FIGS. 19A to 19C, thereby forming a trench following the shape of the sensor unit 20 and the cavity 13.

An oxide film is then deposited on the inner wall surface of the trench. The oxide film on the bottom wall surface of the trench is then removed by etching. While the cavity 13 is being formed by removing the bottom of the trench by isotropic etching, the sensor unit 20 is formed at the same time, the sensor unit 20 being supported by the anchor 21 inside the cavity 13 and released and separated from the bottom wall 14 of the cavity 13, except for the anchor 21, toward the Z2-side.

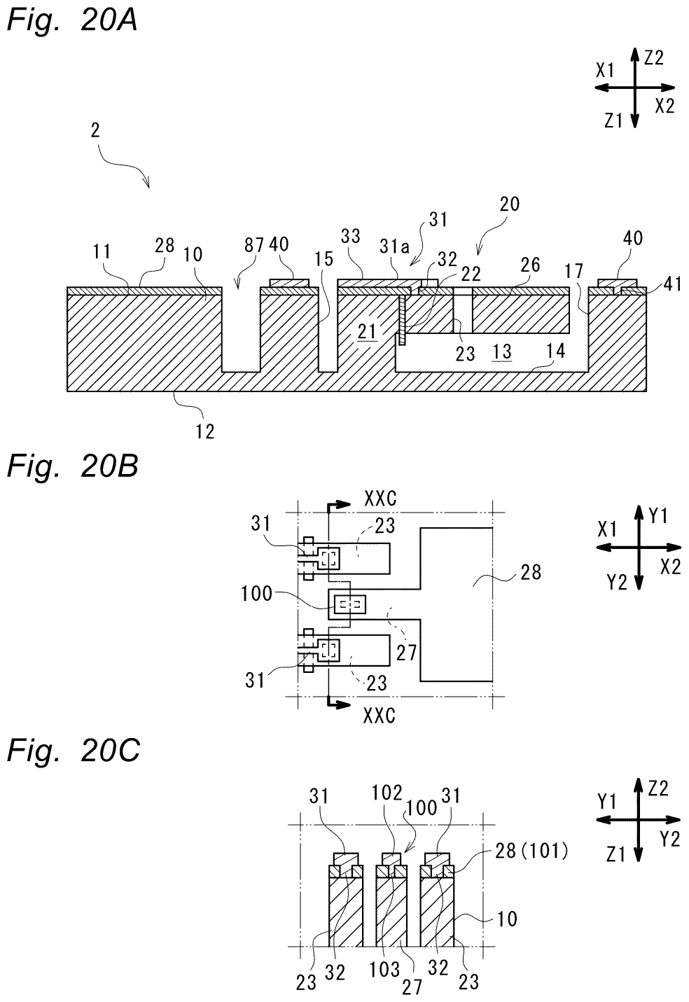

Finally, the silicon oxide on the side walls of the trench is removed by HF vapor etching, and the hard mask 106 is also removed, as illustrated in FIGS. 20A to 20C. A finished device wafer 2 is then achieved. Note that, because the device insulating film 28, which is formed by thermal oxidation, exhibits a lower etching rate (e.g., about 3 times lower) than the etching rate of the hard mask 106, which is formed by CVD, the device insulating film 28 remains without being entirely removed even after being subjected to the HF vapor etching.

On the device wafer 2, a trench 87 extending in the Y direction and recessed toward the Z1-side is formed on the X1-side of the sensor unit 20, and on the X2-side of the electrode pad 57 provided on the cap wafer 3. The trench 87 is formed at the same time as the sensor unit 20 is formed.

### (Bonding Process Between Device Wafer and Cap Wafer)

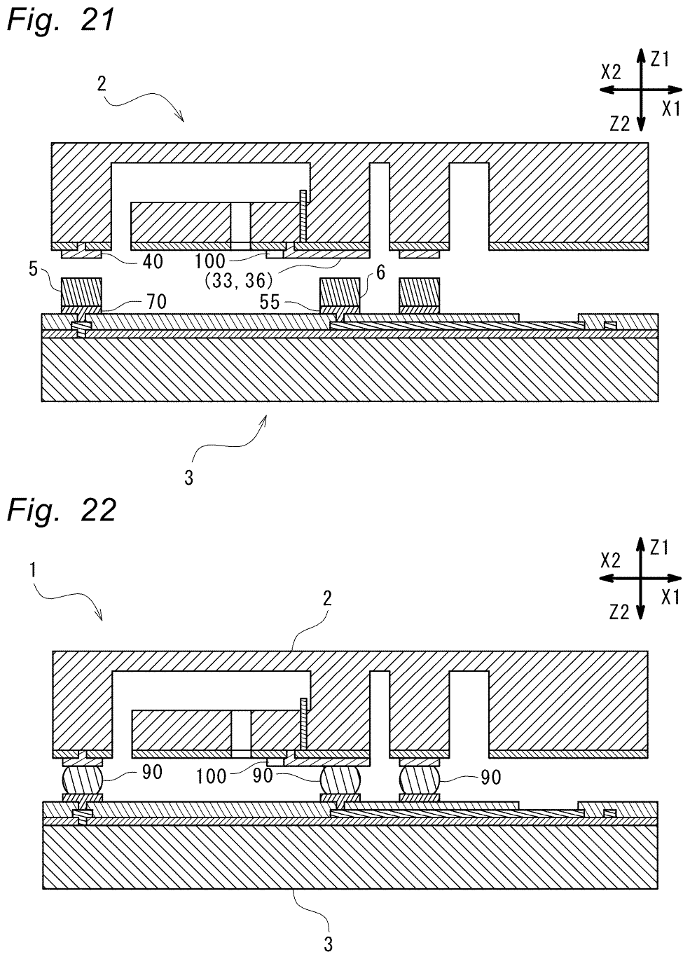

A process of manufacturing the MEMS device 1 by bonding the device wafer 2 and the cap wafer 3 will now be described with reference to FIGS. 21 to 24. As illustrated in FIG. 21, the device wafer 2 is reversed by 180 degrees so as to face the cap wafer 3 in the Z direction. At this time, the positions of the device wafer 2 in the X direction and the Y direction are adjusted so that the two fixed electrode bonding portions 33, one movable electrode bonding portion 36, and the device outer peripheral bonding layer 40 face the three bonding electrodes 55 and the cap outer peripheral bonding layer 70 of the cap wafer 3, respectively, in the Z direction.

The device wafer 2 and the cap wafer 3 are then subjected to high-temperature press, while keeping the two fixed electrode bonding portions 33, the one movable electrode bonding portion 36, and the device outer peripheral bonding layer 40 in abutment against the three bonding electrodes 55 and the cap outer peripheral bonding layer 70 of the cap wafer 3, respectively, as illustrated in FIG. 22.

In the present embodiment, because the bonding layer 4 is formed of the aluminum-germanium eutectic 90 (hereinafter, referred to as an AlGe eutectic material), which is resultant of eutectic reaction of the AlCu layers 55q, 70q and the germanium layers 55r, 70r, the wafers are maintained in abutment against with each other with a force of several kN (for example, 1 kN or more and 100 kN or less) per wafer, under a temperature equal to or higher than 423° C. that is a eutectic point of aluminum and germanium (e.g., equal to or higher than 430° C. and equal to or lower than 500° C.).

At this time, the AlGe eutectic 90 formed as a result of the eutectic reaction goes through a three-phase eutectic reaction to be bonded to the device wirings 30 and the device outer peripheral bonding layer 40 made of polysilicon in the device wafer 2. Because the three-phase eutectic reaction raises the eutectic point (e.g., 500° C. or higher), the eutectic reaction of the AlGe eutectic 90 stops, thereby preventing the diffusion toward the device wiring 30 and the device outer peripheral bonding layer 40.

In the cap wafer 3, by contrast, the TiN layers 55p, 70p acting as barrier layers stop the diffusion of the AlGe eutectic 90 toward the lower layer. The temperature is then lowered to stop the eutectic reaction, and the AlGe eutectic 90 is cured. In this manner, the bonding between the device wafer 2 and the cap wafer 3 is completed.

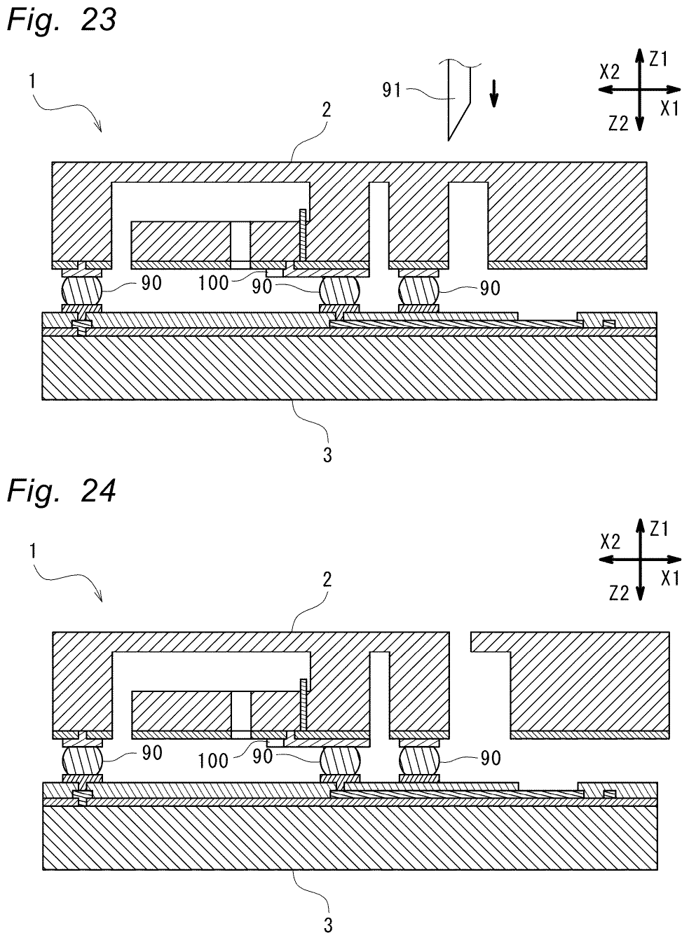

The dicing blade 91 aligned with a position corresponding to the trench 87 is then lowered, as illustrated in FIG. 23, toward the Z2-side. As a result, as illustrated in FIG. 24, the part of the device wafer 2 nearer to the X1-side with respect to the trench 87 is separated, by cutting, and the electrode pads 57 on the cap wafer 3 are exposed to the Z1-side. With this, a finished MEMS device 1 is achieved.

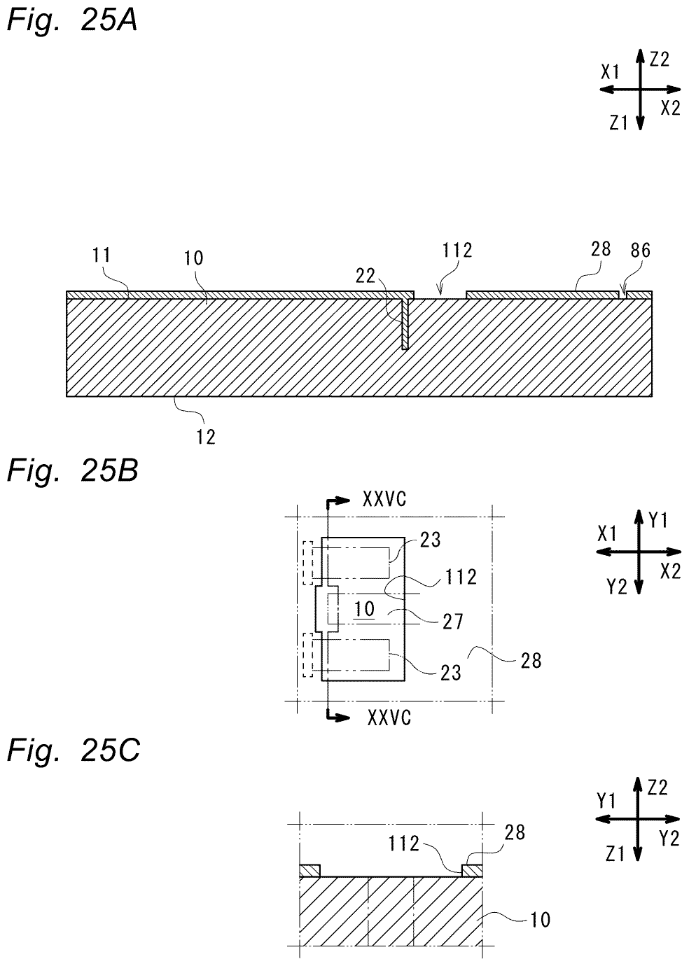

A device wafer 110 and a method of manufacturing the device wafer 110 according to a first modification will now be described with reference to FIGS. 25 to 30. The same reference numerals are used for parts that are the same with those in the above-described embodiment, and the description thereof will be omitted.

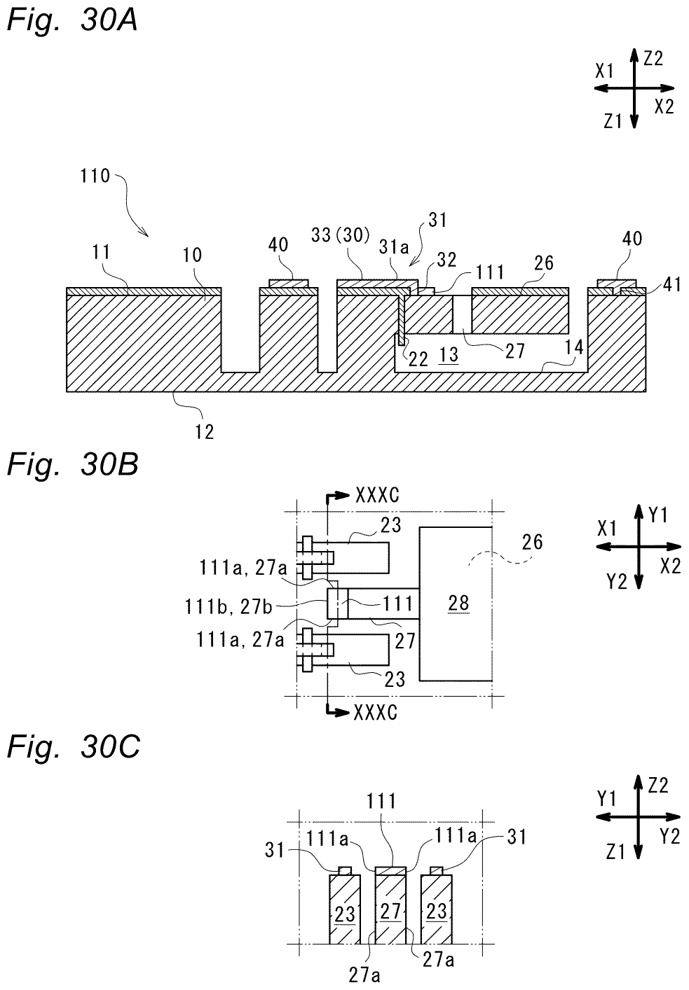

FIGS. 30A to 30C illustrate a finished device wafer 110. Referring to FIG. 30B illustrating the parts around the movable electrode 27, the device wafer 110 is different from the device wafer 2 according to the above-described embodiment in that both edges 111a of the bump stopper 111 in the Y direction that is the short direction of the movable electrode 27, in a view from the Z2-side, are matched with the respective edges 27a of the movable electrode 27 in the Y direction, and that an X1-side tip end 111b of the bump stopper 111 is matched with an X1-side tip 27b of the movable electrode 27.

A process of forming the device wafer 110 will now be described. The first IJs 22 and the second IJ 24 are formed on the device substrate 10, and the device insulating layer 28 is formed on the first principal surface 11, in the same manner as for the device wafer 2 (see FIGS. 13 and 14).

The device insulating layer 28 is then partially removed by etching using a known patterning technique, as illustrated in FIGS. 25A to 25C, thereby forming a via 86 corresponding to the device outer peripheral layer contact 41, and an opening 112 having an opening at least larger than the area corresponding to the movable electrode contact 27 (indicated by a two-dot chain line in FIG. 25B). In the present embodiment, the opening 112 also covers an area on the X2-side with respect to the fixed electrode contacts 32 of the areas corresponding to the pair of respective fixed electrodes 23 (indicated by two-dot chain lines in FIG. 25B), in addition to the area corresponding to the movable electrode 27.

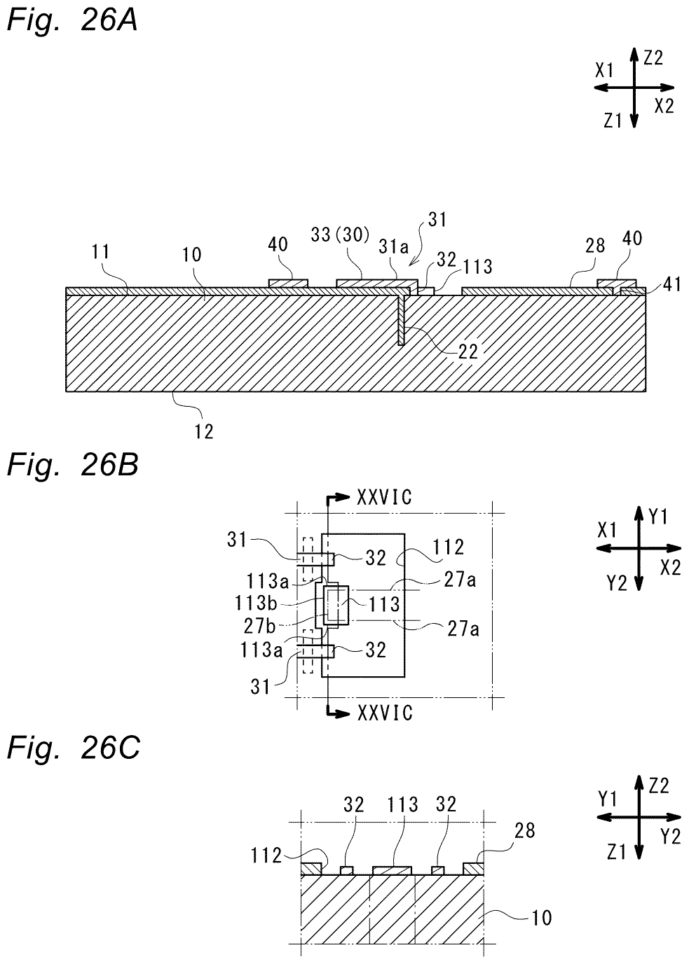

The device wirings 30 and the device outer peripheral bonding layer 40 are then laminated on the Z2-side of the device insulating layer 28, as illustrated in FIGS. 26A to 26C, using a known patterning technique. The fixed electrode contacts 32, the movable electrode contact 35, and the device outer peripheral layer contact 41 are also formed at the same time. The fixed electrode contacts 32 are positioned inside the opening 112. Also inside the opening 112, a bump stopper base 113 is formed on the Z2-side surface of the device substrate 10.

Both edges 113a of the bump stopper base 113 in the Y direction are positioned outside of the respective edges 27a of the movable electrode 27 in the Y direction so that the movable electrode 27 (indicated by a two-dot chain line in FIG. 26B) is disposed on the inner side of the bump stopper base 113 in the Y direction, and an X1-side tip end 113b of the bump stopper base 113 is positioned further on the X1-side of the X1-side tip 27b of the movable electrode 27, in the X direction. In other words, the bump stopper base 113 extends slightly further than the X1-side end of the movable electrode 27, in a view from the Z2-side.

The device wirings 30, the device outer peripheral bonding layer 40, the bump stopper base 113, and the contacts 32, 35, 41 are made of polysilicon doped with a p-type impurity or an n-type impurity at a high concentration, and are formed at the same time, that is, formed in the same layer by low-pressure CVD, for example.

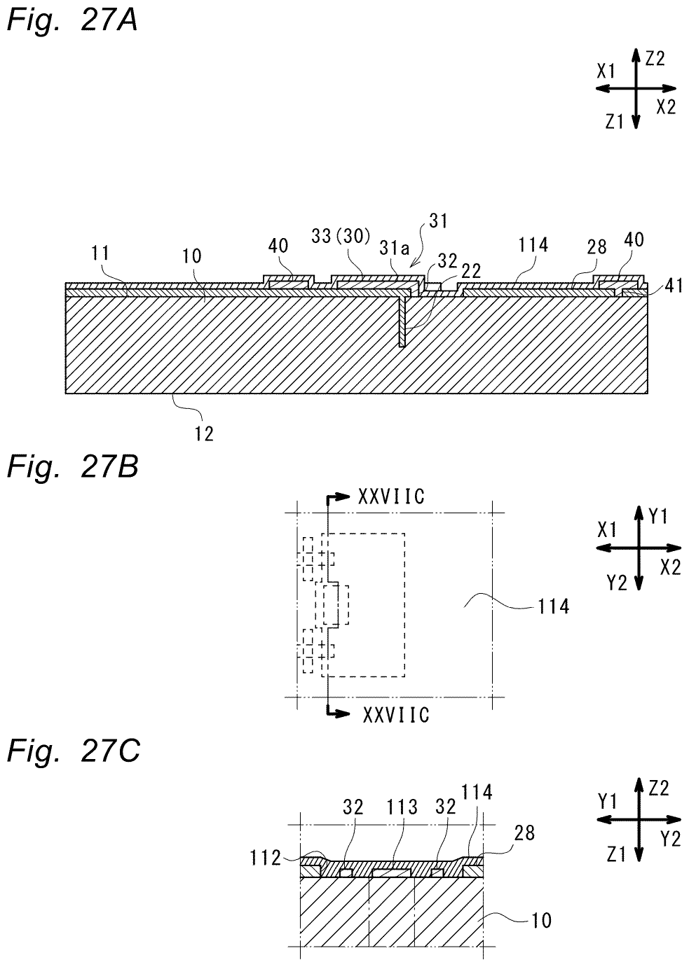

A passivation layer 114 is then is formed on the entire device substrate 10, from the Z2-side, as illustrated in FIGS. 27A to 27C. The passivation layer 114 is an oxide film made of silicon oxide.

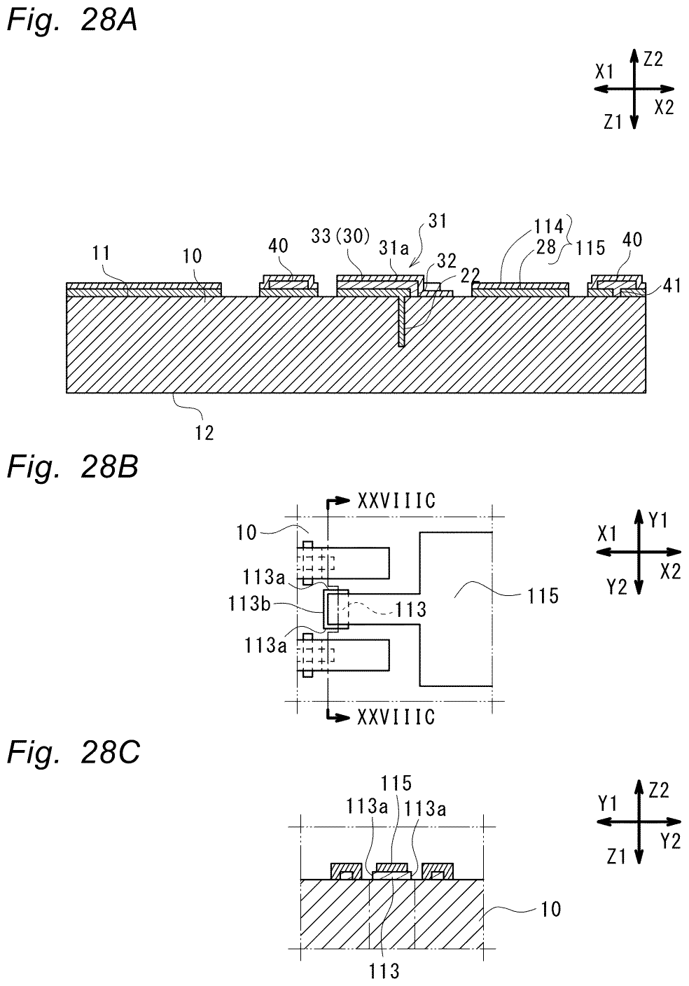

The passivation layer 114 and the device insulating layer 28 are then partially removed by etching, as illustrated in FIGS. 28A to 28C, to form a hard mask 115 that covers a part of the device substrate 10. The hard mask 115 covers a part to be the sensor unit 20 and a part corresponding to the device outer peripheral bonding layer 40, and has an opening in a part where the cavity 13 is to be formed. The device substrate 10 therefore is exposed in the area not covered by the hard mask 115.

At this time, both edges 113a of the bump stopper base 113 in the Y direction and the X1-side tip end 113b of the bump stopper base 113 are not covered by the hard mask 115 and are exposed, because the bump stopper base 113 extends slightly further than the X1-side end of the movable electrode 27.

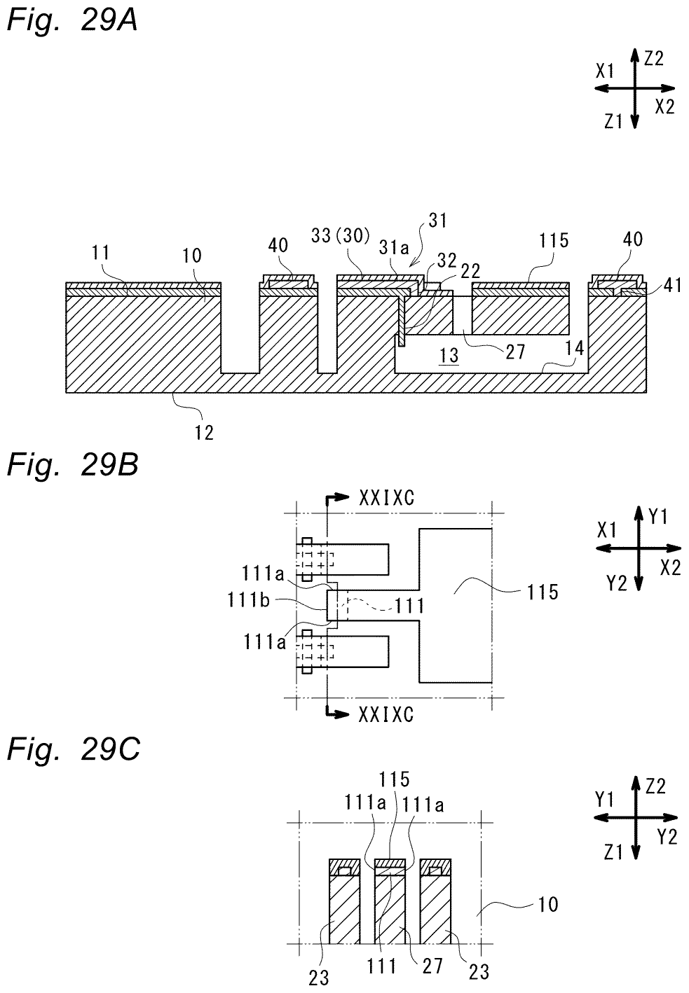

The device substrate 10 is then trenched toward the Z1-side by anisotropic etching using the hard mask 115, as illustrated in FIGS. 29A to 29C, thereby forming a trench following the shape of the sensor unit 20 and the cavity 13.

Because the bump stopper base 113 and the device substrate 10 are etched via the common hard mask 115, the edges 111a of the bump stopper 111, resultant of etching the bump stopper base 113, in the Y direction are matched with the respective edges 27a of the movable electrode 27 in the Y direction, and the X1-side tip end 111b of the bump stopper 111 is matched with the X1-side tip 27b of the movable electrode 27, in a view from the Z2-side.

An oxide film is then deposited on the inner wall surface of the trench. The oxide film on the bottom wall surface of the trench is then removed by etching. While the cavity 13 is being formed by removing the bottom of the trench by isotropic etching, the sensor unit 20 is formed at the same time, the sensor unit 20 being supported by the anchor 21 inside the cavity 13 and released and separated from the bottom wall 14 of the cavity 13, except for the anchor 21, toward the Z2-side.

The silicon oxide on the side walls of the trench is then removed by HF vapor etching, and the hard mask 115 is also removed, as illustrated in FIGS. 30A to 30C. With this, a finished device wafer 110 is then achieved. Note that, because the device insulating film 28, which is formed by thermal oxidation, exhibits a lower etching rate (e.g., about 3 times lower) than the etching rate of the hard mask 115, which is formed by CVD, the device insulating film 28 remains without being entirely removed even after being subjected to the HF vapor etching.

As illustrated in FIG. 30C, in the device wafer 110, the bump stopper 111 is directly laminated on the Z2-side surface of the movable electrode 27, without the device insulating layer 28 interposed therebetween. By performing etching using the common hard mask 115, the bump stopper 111 is formed so that both edges 111a of the bump stopper 111 in the Y direction are matched with the edges 27a of the movable electrode 27 in the Y direction, respectively and the X1-side tip end 111b of the bump stopper 111 is matched with the X1-side tip 27b of the movable electrode 27, in a view from the Z2-side.

In other words, because the bump stopper 111 and the movable electrode 27 are not etched using separate hard masks, there cannot be no misalignment of the bump stopper 111 with respect to the movable electrode 27. Even with a movable electrode 27 having a small width in the short direction in a view from the Z direction, the bump stopper 111 can be formed on the movable electrode 27 without any misalignment. It is also possible to configure the MEMS device 1 by bonding the device wafer 110, instead of the device wafer 2, to the cap wafer 3 via the bonding layer 4.

The MEMS device 1 described above exhibits following effects.

(1) A MEMS device according to one aspect of the present disclosure includes:
a device wafer 2 having a first principal surface 11 and a second principal surface 12 that is on an opposite side of the first principal surface 11;
a cap wafer 3 facing the first principal surface 11 of the device wafer 2; and
a bonding layer 4 that bonds the device wafer 2 and the cap wafer 3,
in which the device wafer 2 includes:
   a device substrate 10 that has a cavity 13 recessed toward a Z1-side from the first principal surface 11 toward the second principal surface 12;
   a sensor unit 20 that is positioned inside the cavity 13 and including a fixed electrode 23 and a movable electrode 27 facing the fixed electrode 23; and
   a bump stopper 100 that is disposed on a surface of the movable electrode 27, the surface being on a side of the first principal surface 11, and that restricts displacement of the movable electrode 27 in a direction moving closer to the cap wafer 3 in the Z direction.

As a result of the bump stopper 100 being provided directly on the Z2-side surface of the movable electrode 27, the misalignment of the bump stopper 100 with respect to the movable electrode 27 can be avoided, without the need for considering the misalignment between the device wafer 2 and the cap wafer 3, as in the configuration in which the bump stopper 100 is provided on the cap wafer 3.

Furthermore, because it is not necessary to provide a bump stopper 100 on the cap wafer 3, the cap wafer 3 is simplified. For example, when the multilayer wiring for an ASIC or the like is to be formed on the cap wafer 3, it is not necessary to remove the multilayer wiring and the passivation layer that may accompany the multilayer wiring, to expose the silicon substrate and to form the bump stopper 100. Therefore, it is possible to simplify the process of forming the cap wafer 3, and to reduce the process cost.

(2) In the short direction (Y direction) of the movable electrode 27 in a view from the Z2-side, the edges 111a of the bump stopper 111 in the Y direction may be matched with the respective edges 27a of the movable electrode 27 in the Y direction.

As a result, by performing structure-etching the device substrate 10, the contour of the bump stopper 111 and the contour of the movable electrode 27 can be formed at the same time.

(3) The bump stopper 100 may have a width smaller than the width of the movable electrode 27 in the short direction (Y-direction) of the movable electrode 27 in a view from the Z2-side.

As a result, it is possible to suppress excessive displacement of the movable electrode 27 toward the Z2-side, while making the bump stopper 100 compact.

(4) The bump stopper 100 may have a surface having a higher surface roughness on a side facing the cap wafer 3, than a surface of the first principal surface 11 of the device substrate 10.

As a result, because the bump stopper 100 has a higher surface roughness, a contact area coming into contact with the cap wafer 3 is reduced. Therefore, the bump stopper 100 does not become adhered to the cap wafer 3, and sticking of the bump stopper 100 to the cap wafer 3 is suppressed.

(5) The bump stopper 100 may be made of an inorganic material that has conductivity.

As a result, the bump stopper 100 does not become electrically charged, so that it is possible to prevent generation of an electrostatic attraction between the bump stopper 100 and the cap wafer 3, so that sticking of the bump stopper 100 to the cap wafer 3 is suppressed.

(6) The cap wafer 3 may have a first cap insulating layer 53 and/or a second cap insulating layer 54, on a part where the bump stopper 100 comes into contact when the movable electrode 27 is displaced closer to the cap wafer 3 in the Z direction.

As a result, no electrostatic attraction is generated between the bump stopper 100 and the cap wafer 3 since the bump stopper 100 does not become electrically charged, even there is some first cap insulating layer 53 and/or second cap insulating layer 54 remaining on the surface on the cap wafer 3. Therefore, it is not necessary to remove the first cap insulating layer 53 and/or the second cap insulating layer 54 from the surface of the cap wafer 3. Hence, it is possible to simplify the process of forming the cap wafer 3 and to reduce the process cost.

(7) The device wafer 2 may further include a device wiring 30 that is electrically connected to the sensor unit 20, and is disposed on the sensor unit 20 on a side of the first principal surface 11, and the bump stopper 100 may be positioned in a same layer as the device wiring 30, and made of a material that is same as a material of the device wiring 30.

As a result, the bump stopper 100 and the device wiring 30 can be formed in the same process, making it unnecessary to form the bump stopper 100 and the device wiring 30 in different layers.

(8) The cap wafer 3 may include a cap wiring 60, and
the device wiring 30 may be directly bonded to the bonding layer 4, and electrically connected to the cap wiring 60 via the bonding layer 4.

As a result, it becomes possible to form the fixed electrode bonding portion 33 and the movable electrode bonding portion 36 to be bonded to the bonding layer 4 in the same process as the process for forming the device wiring 30, making it unnecessary to form the fixed electrode bonding portion 33 and the movable electrode bonding portion 36 in a layer different from the device wiring 30. The device wiring 30 can thus be directly bonded to the bonding layer 4 and electrically connected to the cap wiring 60 via the bonding layer 4.

(9) The cap wafer 3 may include an electrode pad 57 that is electrically connected to the cap wiring 60, and to which an external wiring is connected.

As a result of the electrode pad 57 being positioned on the cap wafer 3, it becomes possible to simplify the device wafer 2, and to improve the accuracy at which the sensor unit 20 is formed, more easily.

(10) The bonding layer 4 may be made of an aluminum germanium alloy.

As a result, the bonding layer 4 can be electrically connected to the device wiring 30 and the cap wiring 60, while bonding the device wafer 2 and the cap wafer 3.

(11) The device wiring 30 (that is, the fixed electrode bonding portions 33 and the movable electrode bonding portion 36) may be made of a material having wettability with respect to the bonding layer 4, and causing no eutectic diffusion.

As a result, while the device wiring 30 is bonded to the bonding layer 4, the device wiring 30 is suppressed from being taken into the bonding layer 4 due to the eutectic reaction, so that disappearance of the device wiring 30 is suppressed.

(12) The bump stopper 100 may be made of a conductive material selected from the group consisting of polysilicon, a polycide alloy, a titanium nitride alloy, and a titanium tungsten alloy.

As a result, it is possible to achieve a bump stopper 100 that is hard enough to prevent wearing upon coming into contact with the cap wafer 3, and that also has conductivity.

(13) A method of manufacturing a MEMS device 1 according to another aspect of the present disclosure includes:
forming a device insulating layer 28 on a Z2-side surface of the device substrate 10;
forming a via 104 via which a surface of the device substrate 10 is exposed, by partially removing the device insulating layer 28;
forming a bump stopper 100 larger than the via 104 in a plan view, by laminating conductive polysilicon on the via 104 and on a part surrounding the via 104 on the device insulating layer 28;
further covering a surface of the device substrate 10 on the Z2-side, with a passivation layer 105;
forming a hard mask 106 by partially removing the passivation layer 105 and the device insulating layer 28, the hard mask 106 being larger than the bump stopper 100 so that at least the bump stopper 100 is covered by the hard mask 106, and the hard mask 106 having a shape corresponding to the sensor unit 20;
performing structure etching in which the device substrate 10 is removed by being etched using the hard mask 106 to form an outline of the sensor unit 20; and
obtaining the sensor unit 20 having a narrow bump stopper 100, on a surface of the sensor unit 20, by removing the hard mask 106.

As a result, it is possible to form a narrow bump stopper 100 accurately, on the Z2-side surface of the movable electrode 27.

(14) A method for manufacturing a MEMS device 1 according to still another aspect of the present disclosure includes:
forming a device insulating layer 28 on a Z2-side surface of the device substrate 10;
forming the opening 112 via which the surface of the device substrate 10 is exposed by partially removing the device insulating layer 28;
laminating polysilicon in the opening 112, in a size smaller than the opening 112;
further covering the Z2-side surface of the device substrate 10 with a passivation layer 114;
forming a hard mask 115 by partially removing the passivation layer 114 and the device insulating layer 28, the hard mask 115 having a shape corresponding to the sensor unit 20;
performing structure etching in which the device substrate 10 is removed by being etched using the hard mask 115 to form outlines of the sensor unit 20 and the bump stopper 111 simultaneously; and
forming a sensor unit 20 having the same width as the bump stopper 111 on the surface of the sensor unit 20, by removing the hard mask 115.

As a result, the contours of the bump stopper 111 and the movable electrode 27 can be formed simultaneously, by structure etching. Even when the movable electrode 27 has a small width, it is possible to laminate the bump stopper 111 on the movable electrode 27 without any misalignment.

(15) The device wiring 30 that is electrically connected to the sensor unit 20 may be formed on the same layer as the bump stopper 100.

As a result, the bump stopper 100 and the device wiring 30 can be formed in the same process.

(16) The device wafer 2 having the device substrate 10 and the sensor unit 20 may be bonded to the cap wafer 3 via the bonding layer 4, and
the device wiring 30 may be directly bonded to the bonding layer 4.

As a result, because it is not necessary to separately form a portion to be bonded for bonding the device wafer 2 to the bonding layer 4, in a different layer from the device wiring 30, it is possible to simplify the process of forming the device wafer 2, and to reduce the process cost.

(17) The MEMS device 1 includes:
a device wafer 2 that includes: a device substrate 10 that has a first principal surface 11 and a second principal surface 12 that is on an opposite side of the first principal surface 11, and that has a cavity 13 recessed toward a Z1-side from the first principal surface 11 toward the second principal surface 12; and a sensor unit 20 positioned inside the cavity 13, mechanically connected to and electrically insulated from the device substrate 10 by a single anchor 21, and that also includes a device wiring 30 electrically connected to the sensor unit 20;
a cap wafer 3 that includes: a cap substrate 50 facing the device wafer 2 from a side of the first principal surface 11; and a cap wiring 60 electrically connected to the device wiring 30; and
a bonding layer 4 for bonding the device wafer 2 and the cap wafer 3,
in which the device wiring 30 is directly bonded to the bonding layer 4, and electrically connected to the cap wiring 60 via the bonding layer 4.

As a result of the sensor unit 20 being mechanically connected to the single anchor 21, the external strain transmitted to the sensor unit 20 takes a single path. As a result, the external strain transmitted to the sensor unit 20 affects the sensor unit 20 uniformly. Therefore, it becomes easier to stabilize the detection characteristics of the sensor unit 20, and the zero-point offset is reduced.

Furthermore, because the device wiring 30 is directly bonded to the bonding layer 4, it is not necessary to provide a bonding portion separate from the device wiring 30 to the device wafer 2. Therefore, it becomes easier to simplify the structure of the device wafer 2. As a result, the number of laminated layers in the device wafers 2 is reduced. Hence, it becomes easier to simplify the process of forming the device wafers 2, and to form the sensor unit 20 on the device substrate 10 easily and accurately. With this, a variation in the shape of the sensor unit 20 is reduced, so that the zero-point offset due to the variation is suppressed.

By contrast, in a configuration in which the sensor unit is connected to a plurality of anchors, the external strain input to the sensor unit follows a plurality of input paths, and therefore, the strain affects the sensor unit non-uniformly. The sensor unit is therefore likely to become strained non-uniformly, and to exhibit a variation in the detection characteristics. In addition, in a configuration in which a bonding portion separate from the device wiring is provided on the device wafer, the number of laminated layers in the device wafer increases. Therefore, the process of forming the device wafer tends to be more complicated, and it is more likely for the shape of the sensor unit to vary. Hence, in a configuration in which the sensor unit has a plurality of anchors and/or the sensor unit has a bonding portion in a layer different from the device wiring on the device wafer, as in the conventional structure, it is more difficult to suppress the zero-point offset.

(18) The sensor unit 20 includes:
an anchor 21 fixed to a wall surface by which the cavity 13 is defined;
a fixed electrode 23 mechanically connected to and electrically insulated from the anchor 21 via a first IJ 22, and extending in the X direction;
a spring 25 mechanically connected to and electrically insulated from the anchor 21 via a second IJ 24;
a mass 26 mechanically coupled to and electrically connected to the spring 25;
a movable electrode 27 mechanically connected and electrically connected to the mass 26, extending in the X direction, and facing the fixed electrode 23 in the Y direction; and
a device insulating layer 28 laminated on a side of the first principal surface 11, on the anchor 21, on the fixed electrode 23 at least an area near the first IJ 22, on an area over the spring 25, the mass 26, and the movable electrode 27 in at least an area near the second IJ 24,
in which the sensor unit 20, excluding the anchor 21, is spaced apart from the bottom wall 14 of the cavity 13 on the Z2-side, and
the device wiring 30 includes:
   a fixed electrode wiring 31 laminated on the device insulating layer 28, and extending from a fixed electrode contact 32 that is positioned correspondingly to the fixed electrode 23 in a view from a side of the first principal surface 11, that penetrates the device insulating layer 28, and that electrically connected to the fixed electrode 23, the fixed electrode wiring 31 traversing the first IJ 22 and extending to the fixed electrode bonding portion 33; and
   a movable electrode wiring 34 laminated on the device insulating layer 28, extending from the movable electrode contact 35 that is positioned correspondingly to the spring 25, the mass 26, or the movable electrode 27 in a view from the side the first principal surface 11, that penetrates the device insulating layer 28, and that electrically connected to the spring 25, the mass 26, or the movable electrode 27, the movable electrode wiring 34 traversing the second IJ 24 and extending to the movable electrode bonding portion 36,
in which the device wiring 30 is bonded to the cap wiring 60 via the bonding layer 4 at the fixed electrode bonding portion 33 and the movable electrode bonding portion 36, and
the device wiring 30 and the cap wiring 60 are electrically connected.

As a result, with a vertical separation that uses an isolation joint extending in the Z direction, a structure in which the fixed electrode 23 and the movable electrode 27 are electrically insulated from but being mechanically connected to the single anchor 21 is achieved. With this structure, it is easier to enable the external strain transmitted to the fixed electrode 23 and the movable electrode 27 to affect the fixed electrode 23 and the movable electrode 27 uniformly. In other words, the fixed electrode 23 and the movable electrode 27 are similarly affected by the strain, while maintaining the relative positional relationship therebetween. Therefore, it is easier to stabilize the characteristics of the sensor unit 20 including the fixed electrode 23 and the movable electrode 27.

Furthermore, because, in the device wafer 2, the device wiring 30 also serves as a bonding portion bonded to the bonding layer 4, the device wafer 2 does not need to include separately a wiring layer and a bonding portion. As a result, because the number of lamination processes is reduced as compared with a configuration in which the device wafer 2 includes a larger number of layers, it is possible to form the fixed electrode 23 and the movable electrode 27 more easily and accurately. In this case, a manufacturing variation in the distance between the fixed electrode 23 and the movable electrode 27, for example, is suppressed. Therefore, it is easier to reduce the offset at the zero point without any external force.

Therefore, it is possible to stabilize the output characteristic of the sensor unit 20 regardless of the external strain transmitted to the sensor unit 20, and to improve the detection accuracy.

The present disclosure is not limited to the configurations described above in the embodiment, and various modifications thereof are still possible.

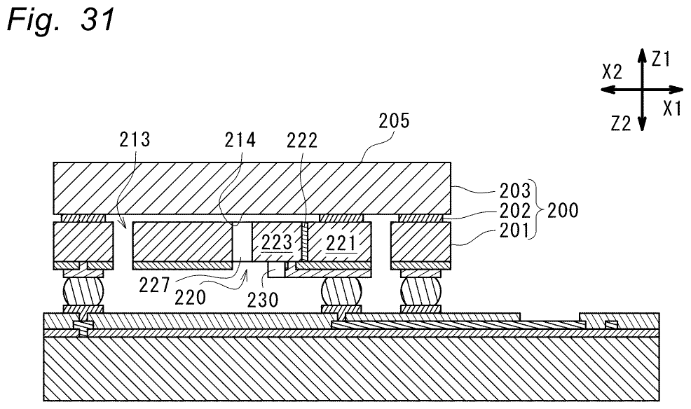

In the embodiment described above, the sensor unit 20 is formed from the device substrate 10 by etching, but the present invention is not limited thereto. For example, FIG. 31 illustrates a cross-sectional view of a device wafer 205 according to a modification along the X-Z plane, and the device wafer 205 is configured as an SOI substrate 200, instead of the device substrate 10.

For example, the SOI substrate 200 includes a first layer 201 that is on the Z2-side, a second layer 202 laminated on the Z1-side of the first layer 201, and a third layer 203 laminated on the Z1-side of the second layer 202. The first layer 201 and the third layer 203 are made of conductive silicon, and the second layer 202 is configured as an insulating layer made of silicon oxide. By providing the first layer 201 with a trench extending toward the Z1-side and reaching the second layer 202, and by partially removing the second layer 202 by HF vapor etching, it is possible to form a sensor unit 220 having an anchor 221 supported by the second layer 202, and a fixed electrode 223 and a movable electrode 227 that extend horizontally from the anchor 221 and that are separated from a bottom wall 214 of a cavity 213 toward the Z2-side.

Furthermore, in order to mechanically connect and electrically insulate the fixed electrode 223 and the movable electrode 227 to and from the anchor 221, a deep trench may be formed in the first layer 201 toward the Z1-side, so as to reach the second layer 202; and the trench may be filled with polysilicon as an insulator. In this manner, a deep trench isolation (DTI) 222 can be formed, to provide a vertical isolation structure extending from the anchor 221 to the fixed electrode 223 and the movable electrode 227 in the Z direction, as the DTI 222. Thus, it is possible to form a device wafer 205 having a sensor unit 220 supported by a single anchor 221 from the SOI substrate 200.

Even in such a configuration, it is possible to form the bump stopper 230 on the Z2-side surface of the movable electrode 227, in the same manner as in the device wafer 2 and the device wafer 110 described above.

In the above embodiment, the bump stopper 100, 111 is formed on the X1-side tip end of the movable electrode 27, but the present invention is not limited thereto. The bump stopper 100, 111 may also be formed at any position in the longitudinal direction of the movable electrode 27. It is also possible to form a plurality of bump stoppers on the movable electrode 27.

### (Supplementary Note)

The MEMS device and method for manufacturing the same according to the present disclosure provides following aspects.

### (Aspect 1)

A MEMS device comprising:
a device wafer having a first principal surface and a second principal surface that is on an opposite side of the first principal surface;
a cap wafer facing the first principal surface of the device wafer; and
a bonding layer that bonds the device wafer and the cap wafer,
wherein the device wafer includes:
   a device substrate that has a cavity recessed in a first direction from the first principal surface toward the second principal surface;
   a sensor unit that is positioned inside the cavity and including a fixed electrode and a movable electrode facing the fixed electrode; and
   a bump stopper that is disposed on a surface of the movable electrode, the surface being on a side of the first principal surface, and that restricts displacement of the movable electrode in a direction moving closer to the cap wafer in the first direction.

### (Aspect 2)

The MEMS device according to aspect 1, wherein, in a view in the first direction, two edges of the bump stopper are matched with two edges of the movable electrode, respectively, the edges being edges in a short direction of the movable electrode.

### (Aspect 3)

The MEMS device according to aspect 1, wherein the bump stopper has a width smaller than a width of the movable electrode, in a short direction of the movable electrode in a view in the first direction.

### (Aspect 4)

The MEMS device according to any one of aspects 1 to 3, wherein the bump stopper has a surface roughness greater than a surface roughness of a first principal surface of the device substrate.

### (Aspect 5)

The MEMS device according to any one of aspects 1 to 4, wherein the bump stopper is made of an inorganic material having conductivity.

### (Aspect 6)

The MEMS device according to aspect 5, wherein the cap wafer includes a passivation layer that comes into contact with bump stopper when the movable electrode is displaced in the direction moving closer to the cap wafer in the first direction.

### (Aspect 7)

The MEMS device according to any one of aspects 1 to 6, wherein
the device wafer further includes a device wiring that is electrically connected to the sensor unit, and that is disposed on the sensor unit on a side of the first principal surface, and
the bump stopper is positioned in a same layer as the device wiring, and is made of a material that is same as a material of the device wiring.

### (Aspect 8)

The MEMS device according to aspect 7, wherein
the cap wafer includes a cap wiring, and
the device wiring is directly bonded to the bonding layer, and electrically connected to the cap wiring via the bonding layer.

### (Aspect 9)

The MEMS device according to aspect 8, wherein the cap wafer includes an electrode pad that is electrically connected to the cap wiring, and to which an external wiring is connected.

### (Aspect 10)

The MEMS device according to aspect 9, wherein the bonding layer is made of an aluminum germanium alloy.

### (Aspect 11)

The MEMS device according to aspect 10, wherein the device wiring is made of a material having wettability with respect to the bonding layer and causing no eutectic diffusion.

### (Aspect 12)

The MEMS device according to aspect 5 or 11, wherein the bump stopper is made of a conductive material selected from the group consisting of polysilicon, a polycide alloy, a titanium nitride alloy, and a titanium tungsten alloy.

### (Aspect 13)

A MEMS device manufacturing method comprising:
forming an oxide film on a surface of a device substrate;
forming a through hole via which a surface of the device substrate is exposed by partially removing the oxide film;
forming a bump stopper in a size larger than the through hole in a plan view, by laminating a conductive inorganic material in the through hole and on a part of the oxide film, the part surrounding the through hole;
further covering the surface of the device substrate with a passivation layer;
forming a mask by partially removing the passivation layer and the oxide film, the mask being larger in size than the bump stopper and covering at least the bump stopper, and having a shape corresponding to a sensor unit;
performing structure etching in which the device substrate 10 is removed by being etched using the mask to form a contour line of the sensor unit; and
obtaining a sensor unit having a narrow bump stopper on a surface by removing the mask.

### (Aspect 14)

A MEMS device manufacturing method comprising:
forming an oxide film on a surface of a device substrate;
forming an opening via which a surface of the device substrate is exposed by partially removing the oxide film;
laminating an inorganic material smaller than the opening, inside the opening;
further covering the surface of the device substrate with a passivation layer;
forming a mask by partially removing the passivation layer and the oxide film, and having a shape corresponding to the sensor unit;
performing structure etching in which the device substrate is removed by being etched using the mask to form a contour line of the sensor unit and a contour line of the bump stopper simultaneously; and
forming the sensor unit with a bump stopper having a same width on a surface, by removing the mask.

### (Aspect 15)

The MEMS device manufacturing method according to aspect 13 or 14, further comprising forming a device wiring electrically connected to the sensor unit on a same layer as the bump stopper.

### (Aspect 16)

The MEMS device manufacturing method according to any one of aspects 13 to 15, further comprising:
bonding the device wafer including the device substrate and the sensor unit to a cap wafer via a bonding layer; and
directly bonding the device wiring to the bonding layer.

### EXPLANATION OF REFERENCES

1 MEMS device
2 device wafer
3 cap wafer
4 bonding layer
10 device substrate
13 cavity
14 bottom wall
20 sensor unit
21 anchor
22 first IJ
23 fixed electrode
24 second IJ
25 spring
26 mass
27 movable electrode
27a both edges in Y direction
27 X1-side tip
28 device insulating layer
30 device wiring
31 fixed electrode wiring
32 fixed electrode contact
33 fixed electrode bonding portion
34 movable electrode wiring
35 movable electrode contact
36 movable electrode bonding portion
40 device outer peripheral bonding portion
41 device outer peripheral layer contact
50 cap substrate
53 first cap insulating layer
54 second cap insulating layer
55 bonding electrode
56 bonding electrode contact
57 electrode pad
58 cap wiring contact
60 cap wiring
70 cap outer peripheral bonding layer
71 cap outer peripheral layer contact
90 AlGe eutectic
100 bump stopper
100a both edges in Y direction
105 passivation layer
106 hard mask
111 bump stopper
111a both ends in Y direction
111b X1-side tip
114 passivation layer
115 hard mask

What is claimed is:

1. A MEMS device comprising:
a device wafer having a first principal surface and a second principal surface that is on an opposite side of the first principal surface;
a cap wafer facing the first principal surface of the device wafer; and
a bonding layer that bonds the device wafer and the cap wafer,
wherein the device wafer includes:
a device substrate that has a cavity recessed in a first direction from the first principal surface toward the second principal surface;
a sensor unit that is positioned inside the cavity and including a fixed electrode and a movable electrode facing the fixed electrode; and
a bump stopper that is disposed on a surface of the movable electrode, the surface being on a side of the first principal surface, and that restricts displacement of the movable electrode in a direction moving closer to the cap wafer in the first direction.

2. The MEMS device according to claim 1, wherein, in a view in the first direction, two edges of the bump stopper are matched with two edges of the movable electrode, respectively, the edges being edges in a short direction of the movable electrode.

3. The MEMS device according to claim 1, wherein the bump stopper has a width smaller than a width of the movable electrode, in a short direction of the movable electrode in a view in the first direction.

4. The MEMS device according to claim 1, wherein the bump stopper has a surface roughness greater than a surface roughness of a first principal surface of the device substrate.

5. The MEMS device according to claim 1, wherein the bump stopper is made of an inorganic material having conductivity.

6. The MEMS device according to claim 5, wherein the cap wafer includes a passivation layer that comes into contact with bump stopper when the movable electrode is displaced in the direction moving closer to the cap wafer in the first direction.

7. The MEMS device according to claim 1, wherein
the device wafer further includes a device wiring that is electrically connected to the sensor unit, and that is disposed on the sensor unit on a side of the first principal surface, and
the bump stopper is positioned in a same layer as the device wiring, and is made of a material that is same as a material of the device wiring.

8. The MEMS device according to claim 7, wherein
the cap wafer includes a cap wiring, and
the device wiring is directly bonded to the bonding layer, and electrically connected to the cap wiring via the bonding layer.

9. The MEMS device according to claim 8, wherein the cap wafer includes an electrode pad that is electrically connected to the cap wiring, and to which an external wiring is connected.

10. The MEMS device according to claim 9, wherein the bonding layer is made of an aluminum germanium alloy.

11. The MEMS device according to claim 10, wherein the device wiring is made of a material having wettability with respect to the bonding layer and causing no eutectic diffusion.

12. The MEMS device according to claim 5, wherein the bump stopper is made of a conductive material selected from the group consisting of polysilicon, a polycide alloy, a titanium nitride alloy, and a titanium tungsten alloy.

13. The MEMS device according to claim 11, wherein the bump stopper is made of a conductive material selected from the group consisting of polysilicon, a polycide alloy, a titanium nitride alloy, and a titanium tungsten alloy.

14. A MEMS device manufacturing method comprising:
forming an oxide film on a surface of a device substrate;
forming a through hole via which a surface of the device substrate is exposed by partially removing the oxide film;
forming a bump stopper in a size larger than the through hole in a plan view, by laminating a conductive inorganic material in the through hole and on a part of the oxide film, the part surrounding the through hole;
further covering the surface of the device substrate with a passivation layer;
forming a mask by partially removing the passivation layer and the oxide film, the mask being larger in size than the bump stopper and covering at least the bump stopper, and having a shape corresponding to a sensor unit;
performing structure etching in which the device substrate is removed by being etched using the mask to form a contour line of the sensor unit; and
obtaining a sensor unit having a narrow bump stopper on a surface by removing the mask.

15. A MEMS device manufacturing method comprising:
forming an oxide film on a surface of a device substrate;
forming an opening via which a surface of the device substrate is exposed by partially removing the oxide film;
laminating an inorganic material smaller than the opening, inside the opening;
further covering the surface of the device substrate with a passivation layer;
forming a mask by partially removing the passivation layer and the oxide film, and having a shape corresponding to the sensor unit;
performing structure etching in which the device substrate is removed by being etched using the mask to form a contour line of the sensor unit and a contour line of the bump stopper simultaneously; and
forming the sensor unit with a bump stopper having a same width on a surface, by removing the mask.

16. The MEMS device manufacturing method according to claim 14, further comprising forming a device wiring electrically connected to the sensor unit on a same layer as the bump stopper.

17. The MEMS device manufacturing method according to claim 15, further comprising forming a device wiring electrically connected to the sensor unit on a same layer as the bump stopper.

18. The MEMS device manufacturing method according to claim 16, further comprising:
bonding the device wafer including the device substrate and the sensor unit to a cap wafer via a bonding layer; and
directly bonding the device wiring to the bonding layer.

19. The MEMS device manufacturing method according to claim 17, further comprising:
bonding the device wafer including the device substrate and the sensor unit to a cap wafer via a bonding layer; and
directly bonding the device wiring to the bonding layer.
